(19) United States
(12) Patent Application Publication
(10) Pub. No.: US 2001/0026570 A1
(43) Pub. Date: Oct. 4, 2001

(54) Modulator-integrated wavelength-selecting light emitting device and method of controlling the same

(76) Inventors: Yukihiro Hisanaga, Tokyo (JP); Takao Morimoto, Tokyo (JP); Masayuki Yamaguchi, Tokyo (JP)

Correspondence Address: SUGHRUE, MION, ZINN, MACPEAK & SEAS, 2100 Pennsylvania Avenue, N.W., Washington, DC, 20037, US

(21) Appl. No.: 09/813,913

(22) Filed: Mar. 22, 2001

(30) Foreign Application Priority Data
Mar. 22, 2000 (JP) 2000-080867
Feb. 23, 2001 (JP) 2001-049478

(51) Int. Cl. H01S 5/00

(52) U.S. Cl. 372/45

(57) ABSTRACT

The present invention provides a method of controlling a wavelength-selective light emitting device comprising an array of plural semiconductor laser diodes differing in diffraction grating pitch; at least a multiplexer; and at least a modulator, wherein an absorption edge wavelength of the modulator is controlled following to an oscillation wavelength of selected one of the plural laser diodes.

### BACKGROUND OF THE INVENTION

The present invention relates to a semiconductor laser device with a wavelength-selecting function, and more particularly to a semiconductor laser device having a monolithical integration of a distributed feed-back semiconductor laser array having diffraction gratings different in period, optical multiplexers, optical amplifiers and modulators.

The recent rapid distribution of the internet needs an establishment of an optical fiber network communication, wherein a wavelength division multiplexing commination is effective, for which reason the commercial field of the wavelength division multiplexing commination has been on the rapid and great increase. The realization of the wavelength division multiplexing commination needs a large number of modulator-integrated light sources. Further, a large number of modulator-integrated wavelength-selecting light sources is needed as being responsible to plural wavelengths of emitted lights for backup to the light source and a system for switching wavelength. This modulator-integrated wavelength-selecting light source is one of the key devices

Japanese laid-open patent publications Nos. 4-72783 and 5-75202 disclose wavelength-tunable laser diodes, wherein a heat resistive film is provided adjacent to an active layer for causing temperature variation of an optical waveguide to tune or vary the wavelength of the emitted laser beam. The temperature increase causes a reduction in optical output of the laser diode. The tunable range is, actually, however, limited.

Japanese laid-open patent publications Nos. 3-286587 and 8-153928 disclose wavelength-selecting light sources, wherein an array of plural laser diodes and multiplexers are integrated. The laser array may comprise a plurality of a distributed feed-back semiconductor laser diodes having diffraction gratings which are different in pitch from each other. Alternatively, the laser array may comprise a plurality of a distributed Bragg reflector semiconductor laser diodes having diffraction gratings which are different in pitch from each other. The effective laser diode is switched to select the wavelength of the laser emission. In accordance with this conventional structure, if a single laser diode is tunable in wavelength of the laser emission in about 2 nanometers range to about 4 nanometers range, then the arrays of four or eight laser diodes different in wavelength bands are integrated in a single chip for totally responding to the wide wavelength band of 6 nanometers to 25 nanometers for the single chip.

The method of tuning the wavelength of the laser emission from one of the plural wavelength-selecting light sources is disclosed in Japanese laid-open patent publication No. 3-286587, wherein a refractive index of the optical waveguide is controlled or varied by a current injection. Another method of controlling or varying the refractive index of the optical waveguide is also available by a temperature control. The temperature control to the chip is essential for obtaining a stable wavelength of the laser emission. For example, the temperature control at ±10° C. enables a ±1 nanometer control to the wavelength of the laser emission. Usually, the wavelength control to the single laser diode is made by the temperature control.

In Japanese laid-open patent publication No. 3-286587, the multiplexer comprises a star-coupler. In a literature “1999 electron information communication society SC-3-5 entitled “micro-array technique for minimizing PIC for wavelength division multiplexing”, the multiplexer comprises a multi-mode interference multiplexer. The multi-mode interference multiplexer is suitable for reducing an excess loss, for example, not more than 1 dB. If the eight laser diode arrays are multiplexed, then theoretically 9 dB of branching loss is caused. For this reason, a semiconductor optical amplifier is provided for power comsumption after the multiplexing operation.

FIG. 1 is a schematic perspective view illustrative of a first conventional modulator-integrated wavelength-selective light emitting device having a multi-mode interference multiplexer and four arrays of distributed feed-back laser diodes. The wavelength-selective light source comprises a distributed feed-back laser diode section 1, a multi-mode interference multiplexer section 2, a semiconductor optical amplifier section 3 and a modulator section 4, which are monolithically integrated over an InP substrate 5. The distributed feed-back laser diode section 1, the multi-mode interference multiplexer section 2, the semiconductor optical amplifier section 3 and the modulator section 4 are aligned in this order in a first lateral direction, along which a laser beam is emitted. The multi-mode interference multiplexer section 2 is positioned between the distributed feed-back laser diode section 1, and the semiconductor optical amplifier section 3. The semiconductor optical amplifier section 3 is positioned between the multi-mode interference multiplexer section 2 and the modulator section 4. The distributed feed-back laser diode section 1 is bounded from the multi-mode interference multiplexer section 2 by a boundary line extending in a second lateral direction perpendicular to the first lateral direction. The multi-mode interference multiplexer section 2 is also bounded from the semiconductor optical amplifier section 3 by a boundary line extending in the second lateral direction. The semiconductor optical amplifier section 3 is also bounded from the modulator section 4 by the boundary line extending in the second lateral direction.

The distributed feed-back laser diode section 1 has an array of a first distributed feed-back laser diode 6, a second distributed feed-back laser diode 7, a third distributed feed-back laser diode 8, and a fourth distributed feed-back laser diode 9. The first and fourth distributed feed-back laser diodes 6 and 9 are positioned outside, whilst the second and third distributed feed-back laser diodes 7 and 8 are positioned inside, The first distributed feed-back laser diode 6 has a first distributed feed-back laser diode electrode 10 which extends outwardly in parallel to the second lateral direction in the distributed feed-back laser diode section 1. The fourth distributed feed-back laser diode 9 has a fourth distributed feed-back laser diode electrode 13 which extends outwardly in parallel to the second lateral direction in the distributed feed-back laser diode section 1. The second distributed feed-back laser diode 7 has a second distributed feed-back laser diode electrode 11 which extends in the first lateral direction and further extends outwardly in parallel to the second lateral direction over a silicon dioxide cover film on the multi-mode interference multiplexer section 2. The third distributed feed-back laser diode 8 has a third distributed feed-back laser diode electrode 12 which extends in the first lateral direction and further extends outwardly in parallel to the second lateral direction over the silicon dioxide cover film on the multi-mode interference multiplexer section 2.

The multi-mode interference multiplexer section 2 has a multi-mode interference multiplexer which is coupled to the first, second, third and fourth distributed feed-back laser diodes 6, 7, 8 and 9. The multi-mode interference multiplexer section 2 also has the silicon dioxide cover layer. The semiconductor optical amplifier section 3 has a semiconductor optical amplifier which is coupled to the multi-mode interference multiplexer. The semiconductor optical amplifier has an optical amplifier electrode 14 extending in the second lateral direction. The optical amplifier electrode 14 has a large area because the semiconductor optical amplifier does not conduct the modulation. The modulator section 4 has an optical modulator which is coupled to the semiconductor optical amplifier. The optical modulator performs a high speed modulation. The optical modulator has a modulator electrode which has a small area for enabling the optical modulator to perform the high speed modulation. A common electrode 16 is provided on a bottom surface of the InP substrate 5. The first conventional modulator-integrated wavelength-selective light emitting device has first and second facets, wherein the first facet is positioned in an output side and adjacent to the modulator section 4. The first facet is coated with an anti-reflective coating film 17 and further has a window structure, wherein a reflection factor is suppressed to be not more than 0.1%.

It is important for the first conventional modulator-integrated wavelength-selective light emitting device that a detuning quantity which is defined to be a subtraction of a gain peak wavelength from an oscillation wavelength of the distributed feed-back laser diode is controlled within a predetermined range, for example, from −20 nanometers to 0 nanometer. The wavelength detuning is made in the minus direction in order to ensure a resistivity or tolerance to a reflected light from the first facet in the output side. The quantify of the wavelength detuning is limited within 20 nanometers in order to avoid any substantive drop of the grain.

For this technique, the Japanese laid-open patent publications Nos. 8-153928 and 10-117040 disclose that a width of the silicon dioxide film in the laser region is adjusted in accordance with a pitch of the diffraction grating, so that plural multiple quantum well active layers are different in composition from each other, whereby the detuning range is properly set in response to the change or switch of the oscillation wavelength. If the wavelength of the distributed feed-back laser diode is changed or switched, then no deterioration of the device performance is caused.

In Japanese laid-open patent publication No. 3-286587, the modulators are formed in an array. Notwithstanding, in FIG. 1, the single modulator is provided for causing an advantage in shortening the layout path of the electrode for response to the high speed modulation.

The provision of the single modulator, however, causes a disadvantage in that it is difficult to optimize the difference between the oscillation wavelength of the distributed feed-back laser diode and the absorption edge wavelength of the modulator for each of the arrays. One of the plural distributed feed-back laser diodes different in wavelength of the laser emissions is selected for a laser emission at a selected wavelength. Switching the distributed feed-back laser diode causes switching the wavelength of the laser emission, for which reason the single modulator is unable to render the absorption edge wavelength follow to the switched wavelength of the laser emission.

In case of a 2.5 Gb/s modulation, the detuning to both the oscillation wavelength of the distributed feed-back laser diode and the absorption edge wavelength of the modulator is required to be in the band width of 15 nanometers or within the range from 55-77 nanometers. This depends on that in case of a 2 V peak-to-peak modulation, an optical extinction is not so large at a center bias and a sufficient extinction can be obtained at 2 V.

If the extinction ratio is increased from 3 dB at the center bias, then crosspoint is I-shaped waveform is displaced from the center, whereby bit errors come likely to be caused. Under the condition of 10 Gb/s, the requirement for the modulation waveform is more strict, for which reason a higher accurate control to the detuning is thus required, for example, in the band width of 10 nanometers or in the narrow range of 60-70 nanometers.

FIG. 2 is a diagram illustrative of variations in temperature, absorption edge wavelength of the modulator and detuning over wavelength of the first conventional modulator-integrated wavelength-selective light emitting device shown in FIG. 1. The wavelength detuning has a variation in the range of 9.6 nanometers depending on the wavelength. This variation range of 9.6 nanometers is closer to the above desired detuning allowable range of 10 nanometers. There is almost no margin of the variation range to the above desired detuning allowable range. This means that a yield is largely low. The performances of FIG. 2 are based on the following conditions. The device has four arrays. A frequency is about 800 GHz. A wavelength range covers 6.4 nanometers. Per one laser, the temperature varies ±0.8 for enabling the wavelength range to cover 1.6 nanometers width. The temperature varies ±8° C. from a center temperature of 26° C. The first distributed feed-back laser diode covers the wavelength band of 1550.0 nanometers ±0.8 nanometers. The second distributed feed-back laser diode responds to the wavelength band of 1551.6 nanometers ±0.8 nanometers. The third distributed feed-back laser diode responds to the wavelength band of 1553.2 nanometers ±0.8 nanometers. The fourth distributed feed-back laser diode responds to the wavelength band of 1554.8 nanometers ±0.8 nanometers. In total of the first to fourth distributed feed-back laser diodes cover the wavelength range of 1549.2 nanometers to 1555.6 nanometers.

If the equivalent refraction index of each of the first to fourth distributed feed-back laser diodes is 3.21 at 26° C., a first diffraction grating pitch of the first distributed feed-back laser diode is 241.43 nanometers, a second diffraction grating pitch of the second distributed feed-back laser diode is 241.68 nanometers, a third diffraction grating pitch of the third distributed feed-back laser diode is 241.93 nanometers, and a fourth diffraction grating pitch of the fourth distributed feed-back laser diode is 242.18 nanometers. The method of controlling the diffraction grating pitch is disclosed in Japanese laid-open patent publication No. 8-227838, wherein the diffraction grating pitch is controllable by a weighted-dose allocation for variable-pitch electron beam corrugation.

The oscillation wavelength of the distributed feed-back laser diode has a temperature dependency of 0.1 nanometers/°C. The absorption edge wavelength of the modulator has a temperature dependency of 0.4 nanometers/°C. In response to the temperature variation of 26°C±8° C., the absorption edge wavelength varies at 1489.4±3.2 nanometers. The first wavelength detuning range of the first distributed feed-back laser diode is 60.6±2.4 nanometers. The second wavelength detuning range of the second distributed feed-back laser diode is 62.2±2.4 nanometers. The third wavelength detuning range of the third distributed feed-back laser diode is 63.8±2.4 nanometers. The fourth wavelength detuning range of the fourth distributed feed-back laser diode is 65.4±2.4 nanometers. The total wavelength detuning range has a width of 9.6 nanometers and is ranged from 58.2 nanometers to 67.8 nanometers.

In consideration of the actual manufacturing conditions, a further variation of about a few nanometers is unavoidable. This means it difficult for the conventional device to respond to the requirement at 10 Gb/s. In case of 2,5 Gb/s, a tolerance or a resistivity is small. The manufacturing tolerance is extremely strict. No desirable extinction ratio nor desirable modulation waveform can be obtained, whereby a transmittable distance is short.

The above issue on the inter-relationship between the oscillation wavelength and the detuning to the modulator is also common to the difference between the oscillation wavelength and the gain peak wavelength of the semiconductor optical amplifier. For this reason, switching the oscillation wavelength causes the variation in the gain of the semiconductor optical amplifier.

In the above circumstances, it had been required to develop a novel wavelength-selective light emission device free from the above problem.

### SUMMARY OF THE INVENTION

Accordingly, it is an object of the present invention to provide a novel wavelength-selective tight emission device free from the above problems.

It is a further object of the present invention to provide a novel wavelength-selective light emission device which has a sufficient manufacturing tolerance for an allowable detuning range to both the oscillation wavelength of the laser diode and the absorption edge wavelength of the modulator for obtaining a desired extinction ratio and a desired modulation waveform.

It is a still further object of the present invention to provide a novel wavelength-selective light emission device suppressing variation in gain of the optical amplifier of the amplifier upon switching the oscillation wavelength.

It is yet a further object of the present invention to provide a novel method of controlling a wavelength-selective light emission device free from the above problems.

It is a further object of the present invention to provide a novel method of controlling a wavelength-selective light emission device which has a sufficient manufacturing tolerance for an allowable detuning range to both the oscillation wavelength of the laser diode and the absorption edge wavelength of the modulator for obtaining a desired extinction ratio and a desired modulation waveform.

It is a still further object of the present invention to provide a novel method of controlling a wavelength-selective light emission device suppressing variation in gain of the optical amplifier of the amplifier upon switching the oscillation wavelength.

The present invention provides a method of controlling a wavelength-selective light emitting device comprising: an array of plural semiconductor laser diodes differing in diffraction grating pitch; at least a multiplexer; and at least a modulator, wherein an absorption edge wavelength of the modulator is controlled following to an oscillation wavelength of selected one of the plural laser diodes.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a schematic perspective view illustrative of a first conventional modulator-integrated wavelength-selective light source having a multi-mode interference multiplexer and four arrays of distributed feed-back laser diodes.

FIG. 2 is a diagram illustrative of variations in temperature, absorption edge wavelength of the modulator and detuning over wavelength of the first conventional modulator-integrated wavelength-selective light emitting device shown in FIG. 1.

FIG. 3 is a schematic perspective view illustrative of a novel modulator-integrated wavelength-selective light source having a multi-mode interference multiplexer and four arrays of distributed feed-back laser diodes in a first embodiment in accordance with the present invention.

FIG. 4 is a diagram illustrative of variations in temperature, absorption edge wavelength of the modulator and detuning over wavelength in order to explain a first novel method of controlling the oscillation wavelength of the laser diode and the absorption edge wavelength of the modulator of the novel modulator-integrated wavelength-selective light emitting device shown in FIG. 3 in a first embodiment in accordance with the present invention.

FIGS. 5A and 5B are schematic perspective views illustrative of novel wavelength-selective light emitting devices in sequential steps involved in a novel fabrication method in a first embodiment in accordance with the present invention.

FIG. 6 is a diagram illustrative of variations in temperature, absorption edge wavelength of the modulator and detuning over wavelength in order to explain a second novel method of controlling the oscillation wavelength of the laser diode and the absorption edge wavelength of the modulator of the novel modulator-integrated wavelength-selective light emitting device in a second embodiment in accordance with the present invention.

FIG. 7 is a plane view illustrative of a novel modulator-integrated wavelength-selective light emitting device having a multi-mode interference multiplexer and four arrays of distributed feed-back laser diodes as well as a heating resistance line in a second embodiment in accordance with the present invention.

FIG. 8 is a diagram illustrative of variations in temperature, absorption edge wavelength of the modulator and detuning over wavelength in order to explain a third novel method of controlling the oscillation wavelength of the laser diode and the absorption edge wavelength of the modulator of the novel modulator-integrated wavelength-selective light emitting device in a third embodiment in accordance with the present invention.

FIG. 9 is a plane view illustrative of a novel modulator-integrated wavelength-selective light emitting device having a multi-mode interference multiplexer and four arrays of distributed feed-back laser diodes as well as a heating resistance line in a third embodiment in accordance with the present invention.

FIG. 10 is a diagram illustrative of variations in temperature, absorption edge wavelength of the modulator and detuning over wavelength in order to explain a fourth novel method of controlling the oscillation wavelength of the laser diode and the absorption edge wavelength of the modulator of the novel modulator-integrated wavelength-selective light emitting device in a fourth embodiment in accordance with the present invention.

FIG. 11 is a plane view illustrative of a novel modulator-integrated wavelength-selective light emitting device having a multi-mode interference multiplexer and four arrays of distributed feed-back laser diodes as well as a heating resistance line in a fourth embodiment in accordance with the present invention.

FIG. 12 is a diagram illustrative of variations in temperature, absorption edge wavelength of the modulator and detuning over wavelength in order to explain a fifth novel method of controlling the oscillation wavelength of the laser diode and the absorption edge wavelength of the modulator of the novel modulator-integrated wavelength-selective light emitting device in a fifth embodiment in accordance with the present invention.

FIG. 13 is a plane view illustrative of a novel modulator-integrated wavelength-selective light emitting device having a multi-mode interference multiplexer and four arrays of distributed feed-back laser diodes as well as a heating resistance line in a fifth embodiment in accordance with the present invention.

FIG. 14 is a diagram illustrative of variations in temperature, absorption edge wavelength of the modulator and detuning over wavelength in order to explain a sixth novel method of controlling the oscillation wavelength of the laser diode and the absorption edge wavelength of the modulator of the novel modulator-integrated wavelength-selective light emitting device in a sixth embodiment in accordance with the present invention.

FIG. 15 is a plane view illustrative of a novel modulator-integrated wavelength-selective light emitting device having a multi-mode interference multiplexer and four arrays of distributed feed-back laser diodes as well as a heating resistance line in a sixth embodiment in accordance with the present invention.

FIG. 16 is a diagram illustrative of variations in temperature, absorption edge wavelength of the modulator and detuning over wavelength in order to explain a seventh novel method of controlling the oscillation wavelength of the laser diode and the absorption edge wavelength of the modulator of the novel modulator-integrated wavelength-selective light omitting device in a seventh embodiment in accordance with the present invention.

FIG. 17 is a plane view illustrative of a novel modulator-integrated wavelength-selective light emitting device having a multi-mode interference multiplexer and four arrays of distributed feed-back laser diodes as well as a heating resistance line in a seventh embodiment in accordance with the present invention.

### DISCLOSURE OF THE INVENTION

The first present invention provides a method of controlling a wavelength-selective light emitting device comprising: an array of plural semiconductor laser diodes differing in diffraction grating pitch at least a multiplexer; and at least a modulator, wherein an absorption edge wavelength of the modulator is controlled following to an oscillation wavelength of selected one of the plural laser diodes.

It is preferable that the absorption edge wavelength is controlled by controlling the device in temperature.

It is further preferable that the temperature control is made so as to reduce a difference between variation of the oscillation wavelength of selected one of the plural laser diodes and variation of the absorption edge wavelength of the modulator.

It is further more preferable that the plural semiconductor laser diodes and the modulator are controlled at different temperatures.

It is moreover preferable that the plural semiconductor laser diodes and the modulator are controlled by an external temperature controller which controls an entire region of the device uniformly in combination with applying a current to a resistive line which extends over both a laser diode region having the plural semiconductor laser diodes and a modulator region having the modulators provided the resistive line is different in resistivity between the laser diode region and the modulator region.

It is also preferable that the plural semiconductor laser diodes and the modulator are controlled by an external temperature controller which controls an entire region of the device uniformly in combination with applying a current to a resistive line which extends over a laser diode region having the plural semiconductor laser diodes.

It is also preferable that the plural semiconductor laser diodes and the modulator are controlled by an external temperature controller which controls an entire region of the device uniformly in combination with applying a current to a resistive line which extends over a modulator region having the modulator.

It is also preferable that the plural semiconductor laser diodes and the modulator are controlled by an external temperature controller which controls an entire region of the device uniformly in combination with applying a current to a resistive line which extends over both a laser diode region having the plural semiconductor laser diodes and a multiplexer region having the multiplexer, so that a variation rate of the laser diode region is equal to a variation rate of the multiplexer region.

It is also preferable that the plural semiconductor laser diodes and the modulator are controlled by an external temperature controller which controls an entire region of the device uniformly in combination with applying a current to a resistive line which extends over both a semiconductor optical amplifier region having a semiconductor optical amplifier and a modulator region having the modulator, so that a variation rate of the semiconductor optical amplifier region is equal to a variation rate of the modulator region.

It is also preferable that the plural laser diodes are controlled in temperature in a temperature range having a center value which accords to a center value of the oscillation wavelength range, and a difference between a center value of the oscillation wavelength of selected one of the plural laser diodes and a center value of the absorption edge wavelength of the modulator is uniform for all of the plural laser diodes, and the diffraction grating pitch of each of the plural laser diodes is decided based on the controlled temperature of each of the plural laser diodes.

It is further preferable that the plural semiconductor laser diodes and the modulator are controlled at different temperatures.

It is further more preferable that the plural semiconductor laser diodes and the modulator are controlled by an external temperature controller which controls an entire region of the device uniformly in combination with applying a current to a resistive line which extends over both a laser diode region having the plural semiconductor laser diodes and a modulator region having the modulator, provided the resistive line is different in resistivity between the laser diode region and the modulator region.

It is also preferable that the plural semiconductor laser diodes and the modulator are controlled by an external temperature controller which controls an entire region of the device uniformly in combination with applying a current to a resistive line which extends over a laser diode region having the plural semiconductor laser diodes.

It is also preferable that the plural semiconductor laser diodes and the modulator are controlled by an external temperature controller which controls an entire region of the device uniformly in combination with applying a current to a resistive line which extends over a modulator region having the modulator.

It is also preferable that the plural semiconductor laser diodes and the modulator are controlled by an external temperature controller which controls an entire region of the device uniformly in combination with applying a current to a resistive line which extends over both a laser diode region having the plural semiconductor laser diodes and a multiplexer region having the multiplexer, so that a variation rate of the laser diode region is equal to a variation rate of the multiplexer region.

It is also preferable that the plural semiconductor laser diodes and the modulator are controlled by an external temperature controller which controls an entire region of the device uniformly in combination with applying a current to a resistive line which extends over both a semiconductor optical amplifier region having a semiconductor optical amplifier and a modulator region having the modulator, so that a variation rate of the semiconductor optical amplifier region is equal to a variation rate of the modulator region.

It is also preferable that an entire region of the device is controlled at a uniform temperature which corresponds to selected one of the plural laser diodes, so that the absorption edge wavelength of the modulator follows to the oscillation wavelength of selected one of the plural laser diodes.

The second present invention provides a method of controlling a wavelength-selective light emitting device comprising: a single semiconductor laser diode; a semiconductor optical amplifier ; and a modulator, wherein an absorption edge wavelength of the modulator is controlled following to an oscillation wavelength of selected one of the plural laser diodes.

It is preferable that the absorption edge wavelength is controlled by controlling the device in temperature.

It is further preferable that the temperature control is made so as to reduce a difference between variation of the oscillation wavelength of selected one of the plural laser diodes and variation of the absorption edge wavelength of the modulator.

It is further more preferable that the plural semiconductor laser diodes and the modulator are controlled at different temperatures.

It is moreover preferable that the plural semiconductor laser diodes and the modulator are controlled by an external temperature controller which controls an entire region of the device uniformly in combination with applying a current to a resistive line which extends over a laser diode region having the plural semiconductor laser diodes.

It is also preferable that the plural laser diodes are controlled in temperature in a temperature range having a center value which accords to a center value of the oscillation wavelength range, and a difference between a center value of the oscillation wavelength of selected one of the plural laser diodes and a center value of the absorption edge wavelength of the modulator is uniform for all of the plural laser diodes, and the diffraction grating pitch of each of the plural laser diodes is decided based on the controlled temperature of each of the plural laser diodes.

It is further preferable that the plural semiconductor laser diodes and the modulator are controlled at different temperatures.

It is further more preferable that the plural semiconductor laser diodes and the modulator are controlled by an external temperature controller which controls an entire region of the device uniformly in combination with applying a current to a resistive line which extends over a laser diode region having the plural semiconductor laser diodes.

The third present invention provides a wavelength-selective light emitting device comprising: an array of plural semiconductor laser diodes differing in diffraction grating pitch; at least a multiplexer; at least a modulator; a temperature controller for controlling the device in temperature, so that an absorption edge wavelength of the modulator is controlled following to an oscillation wavelength of selected one of the plural laser diodes.

It is preferable that the temperature controller controls the device in temperature so as to reduce a difference between variation of the oscillation wavelength of selected one of the plural laser diodes and variation of the absorption edge wavelength of the modulator.

It is further preferable that the plural semiconductor laser diodes and the modulator are controlled at different temperatures.

It is further more preferable that the temperature controller comprises: an external temperature controller which controls an entire region of the device uniformly; and a resistive line which extends over both a laser diode region having the plural semiconductor laser diodes and a modulator region having the modulator, provided the resistive line is different in resistivity between the laser diode region and the modulator region.

It is also preferable that the temperature controller comprises: an external temperature controller which controls an entire region of the device uniformly; and a resistive line which extends over a laser diode region having the plural semiconductor laser diodes.

It is also preferable that the temperature controller comprises: an external temperature controller which controls an entire region of the device uniformly; and a resistive line which extends over a modulator region having the modulator.

It is also preferable that the temperature controller comprises: an external temperature controller which controls an entire region of the device uniformly; and a resistive line which extends over both a laser diode region having the plural semiconductor laser diodes and a multiplexer region having the multiplexer, so that a variation rate of the laser diode region is equal to a variation rate of the multiplexer region.

It is also preferable that the temperature controller comprises: an external temperature controller which controls an entire region of the device uniformly; and a resistive line which extends over both a semiconductor optical amplifier region having a semiconductor optical amplifier and a modulator region having the modulator, so that a variation rate of the semiconductor optical amplifier region is equal to a variation rate of the modulator region.

It is also preferable that the temperature controller controls the plural laser diodes in temperature in a temperature range having a center value which accords to a center value of the oscillation wavelength range, and the temperature controller controls the device in temperature so that a difference between a center value of the oscillation wavelength of selected one of the plural laser diodes and a center value of the absorption edge wavelength of the modulator is uniform for all of the plural laser diodes, and the diffraction grating pitch of each of the plural laser diodes is decided based on the controlled temperature of each of the plural laser diodes.

It is further preferable that the temperature controller controls the plural semiconductor laser diodes and the modulator at different temperatures.

It is further more preferable that the temperature controller comprises: an external temperature controller which controls an entire region of the device uniformly; and a resistive line which extends over both a laser diode region having the plural semiconductor laser diodes and a modulator region having the modulator, provided the resistive line is different in resistivity between the laser diode region and the modulator region.

It is also preferable that the temperature controller comprises: an external temperature controller which controls an entire region of the device uniformly; and a resistive line which extends over a laser diode region having the plural semiconductor laser diodes.

It is also preferable that the temperature controller comprises: an external temperature controller which controls an entire region of the device uniformly; and a resistive line which extends over a modulator region having the modulator.

It is also preferable that the temperature controller comprises: an external temperature controller which controls an entire region of the device uniformly; and a resistive line which extends over both a laser diode region having the plural semiconductor laser diodes and a multiplexer region having the multiplexer, so that a variation rate of the laser diode region is equal to a variation rate of the multiplexer region.

It is also preferable that the temperature controller comprises: an external temperature controller which controls an entire region of the device uniformly; and a resistive line which extends over both a semiconductor optical amplifier region having a semiconductor optical amplifier and a modulator region having the modulator, so that a variation rate of the semiconductor optical amplifier region is equal to a variation rate of the modulator region

### PREFERRED EMBODIMENT

FIRST EMBODIMENT:

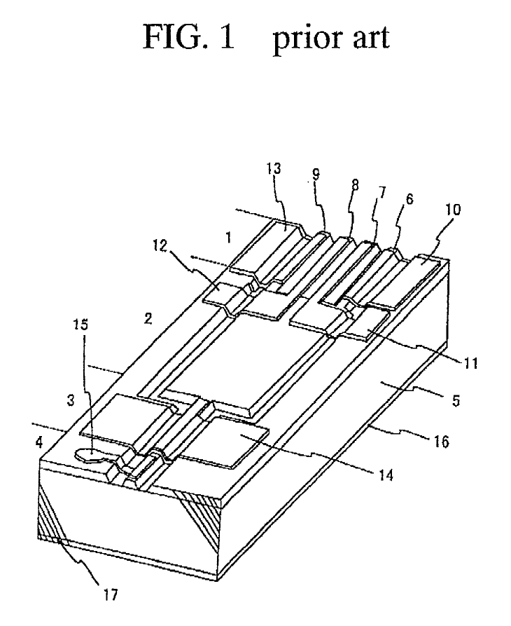

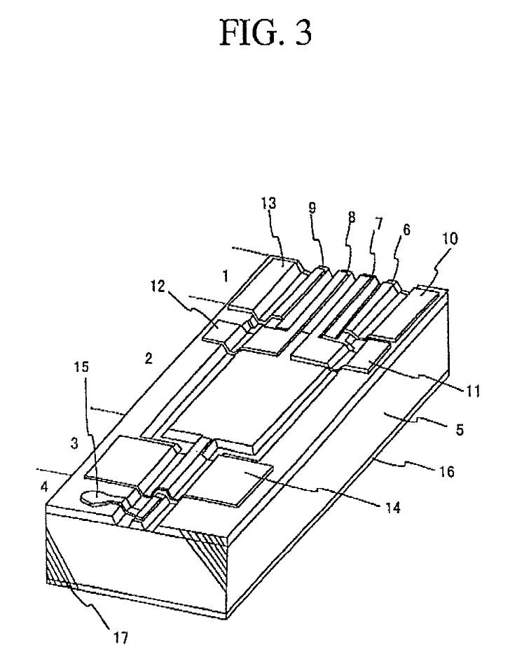

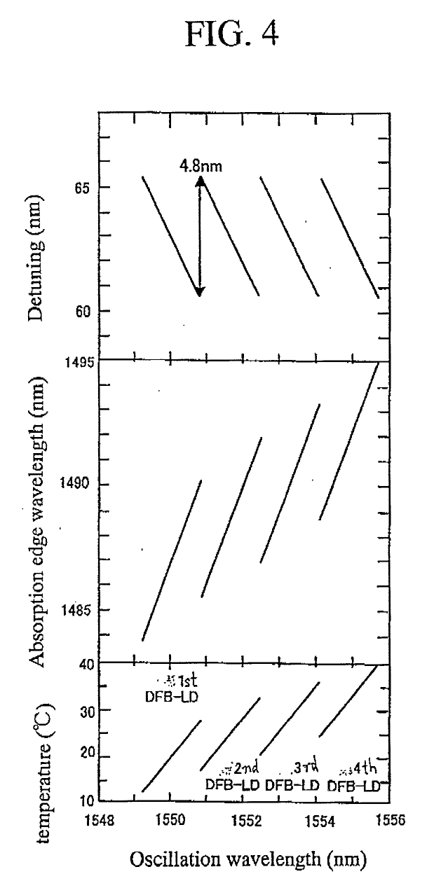

A first embodiment according to the present invention will be described in detail with reference to the drawings. FIG. 3 is a schematic perspective view illustrative of a novel modulator-integrated wavelength-selective light source having a multi-mode interference multiplexer and four arrays of distributed feed-back laser diodes in a first embodiment in accordance with the present invention. FIG. 4 is a diagram illustrative of variations in temperature, absorption edge wavelength of the modulator and detuning over wavelength in order to explain a first novel method of controlling the oscillation wavelength of the laser diode and the absorption edge wavelength of the modulator of the novel modulator-integrated wavelength-selective light emitting device shown in FIG. 3 in a first embodiment in accordance with the present invention. The structure of the novel modulator-integrated wavelength-selective light emitting device of FIG. 3 is different in the pitch of the diffraction grating from the above first conventional modulator-integrated wavelength-selective light emitting device of FIG. 1. The novel modulator-integrated wavelength-selective light emitting device is designed for an optical frequency of 800 GHz and a wavelength of 6.4 nanometers.

As shown in FIG. 3, the novel wavelength-selective light emitting device comprises a distributed feed-back laser diode section 1, a multi-mode interference multiplexer section 2, a semiconductor optical amplifier section 3 and a modulator section 4, which are monolithically integrated over an InP substrate 5. The distributed feed-back laser diode section 1, the multi-mode interference multiplexer section 2, the semiconductor optical amplifier section 3 and the modulator section 4 are aligned in this order in a first lateral direction, along which a laser beam is emitted. The multi-mode interference multiplexer section 2 is positioned between the distributed feed-back laser diode section 1, and the semiconductor optical amplifier section 3. The semiconductor optical amplifier section 3 is positioned between the multi-mode interference multiplexer section 2 and the modulator section 4. The distributed feed-back laser diode section 1 is bounded from the multi-mode interference multiplexer section 2 by a boundary line extending in a second lateral direction perpendicular to the first lateral direction. The multi-mode interference multiplexer section 2 is also bounded from the semiconductor optical amplifier section 3 by a boundary line extending in the second lateral direction, The semiconductor optical amplifier section 3 is also bounded from the modulator section 4 by the boundary line extending in the second lateral direction.

The distributed feed-back laser diode section 1 has an array of a first distributed feed-back laser diode 6, a second distributed feed-back laser diode 7, a third distributed feed-back laser diode 8, and a fourth distributed feed-back laser diode 9. The first and fourth distributed feed-back laser diodes 6 and 9 are positioned outside, whilst the second and third distributed feed-back laser diodes 7 and 8 are positioned inside. The first distributed feed-back laser diode 6 has a first distributed feed-back laser diode electrode 10 which extends outwardly in parallel to the second lateral direction in the distributed feed-back laser diode section 1. The fourth distributed feed-back laser diode 9 has a fourth distributed feed-back laser diode electrode 13 which extends outwardly in parallel to the second lateral direction in the distributed feed-back laser diode section 1. The second distributed feed-back laser diode 7 has a second distributed feed-back laser diode electrode 11 which extends in the first lateral direction and further extends outwardly in parallel to the second lateral direction over a silicon dioxide cover film on the multi-mode interference multiplexer section 2. The third distributed feed-back laser diode 8 has a third distributed feed-back laser diode electrode 12 which extends in the first lateral direction and further extends outwardly in parallel to the second lateral direction over the silicon dioxide cover film on the multi-mode interference multiplexer section 2.

The multi-mode interference multiplexer section 2 has a multi-mode interference multiplexer which is coupled to the first, second, third and fourth distributed feed-back laser diodes 6, 7, 8 and 9. The multi-mode interference multiplexer section 2 also has the silicon dioxide cover layer. The semiconductor optical amplifier section 3 has a semiconductor optical amplifier which is coupled to the multi-mode interference multiplexer. The semiconductor optical amplifier has an optical amplifier electrode 14 extending in the second lateral direction. The optical amplifier electrode 14 has a large area because the semiconductor optical amplifier does not conduct the modulation. The modulator section 4 has an optical modulator which is coupled to the semiconductor optical amplifier. The optical modulator performs a high speed modulation. The optical modulator has a modulator electrode which has a small area for enabling the optical modulator to perform the high speed modulation. A common electrode 16 is provided on a bottom surface of the InP substrate 5. The first conventional modulator-integrated wavelength-selective light emitting device has first and second facets, wherein the first facet is positioned in an output side and adjacent to the modulator section 4. The first facet is coated with an anti-reflective coating film 17 and further has a window structure, wherein a reflection factor is suppressed to be not more than 0.1%. This structure is necessary for preventing optical noises caused by the reflected light from the first facet toward the distributed feed-back laser diode.

The first distributed feed-back laser diode covers the wavelength band of 1550.0 nanometers ±0.8 nanometers, The second distributed feed-back laser diode responds to the wavelength band of 1551.6 nanometers ±0.8 nanometers. The third distributed feed-back laser diode responds to the wavelength band of 1553.2 nanometers ±0.8 nanometers. The fourth distributed feed-back laser diode responds to the wavelength band of 1554.8 nanometers ±0.8 nanometers. In total of the first to fourth distributed feed-back laser diodes cover the wavelength range of 1549.2 nanometers to 1555.6 nanometers.

In accordance with the present invention, the first to fourth distributed feed-back laser diodes receive temperature control in different temperature ranges from each other. For example, the first distributed feed-back laser diode varies 20° C.±8° C. The second distributed feed-back laser diode varies 24° C. ±8° C. The third distributed feed-back laser diode varies 28° C. ±8° C. The fourth distributed feed-back laser diode varies 32° C. ±8° C. The diffraction grating pitch depends on the controlled temperature. The equivalent refraction index of the distributed feed-back laser diode at 26° C. is 3.21. If in accordance with the prior art, the center temperature of the first to fourth distributed feed-back laser diodes are uniform at 26° C., then the first diffraction grating pitch of the first distributed feed-back laser diode is 241.43 nanometers, the second diffraction grating pitch of the second distributed feed-back laser diode is 241.68 nanometers, the third diffraction grating pitch of the third distributed feed-back laser diode is 241.93 nanometers, and the fourth diffraction grating pitch of the fourth distributed feed-back laser diode is 242.18 nanometers. In accordance with the present invention, the center temperature of the first distributed feed-back laser diode is different from 26° C. by −6° C., for which reason it is necessary that the first diffraction grating pitch of the first distributed feed-back laser diode is so set that the first oscillation wavelength is different by 0.6 nanometers. The center temperature of the second distributed feed-back laser diode is different from 26° C. by −2° C., for which reason it is necessary that the second diffraction grating pitch of the second distributed feed-back laser diode is so set that the second oscillation wavelength is different by 0.2 nanometers. The center temperature of the third distributed feed-back laser diode is different from 26° C. by ±2° C., for which reason it is necessary that the third diffraction grating pitch of the third distributed feed-back laser diode is so set that the third oscillation wavelength is different by −0.2 nanometers. The center temperature of the fourth distributed feed-back laser diode is different from 26° C. by ±6° C., for which reason it is necessary that the fourth diffraction grating pitch of the fourth distributed feed-back laser diode is so set that the fourth oscillation wavelength is different by −0.6 nanometers.

Namely, the controlled temperature range of the first distributed feed-back laser diode is set at 20° C.±8° C., and the first diffraction grating pitch of the first distributed feed-back laser diode is 241.53 nanometers. The controlled temperature range of the second distributed feed-back laser diode is set at 24° C.±8° C., and the second diffraction grating pitch of the second distributed feed-back laser diode is 241.71 nanometers. The controlled temperature range of the third distributed feed-back laser diode is set at 28° C.±8° C., and the third diffraction grating pitch of the third distributed feed-back laser diode is 241.90 nanometers. The controlled temperature range of the fourth distributed feed-back laser diode is set at 32° C.±8° C., and the fourth diffraction grating pitch of the fourth distributed feed-back laser diode is 242.09 nanometers. In accordance with the prior art, the adjacent two of the first to fourth distributed feed-back laser diodes are different in diffraction grating pitch by 0.25 nanometers. By contrast, in accordance with the present invention, the adjacent two of the first to fourth distributed feed-back laser diodes are different in diffraction grating pitch by 0.19 nanometers. Namely, if in accordance with the present invention, the center value of the controlled temperature range is different among the first to fourth distributed feed-back laser diodes, then the difference in the diffraction grating pitch between adjacent two of the first to fourth distributed feed-back laser diodes is narrower than when the controlled temperature range is uniform to the first to fourth distributed feed-back laser diodes.

In accordance with the present invention, the center value of the controlled temperature range is different by 4° C. between adjacent two of the first to fourth distributed feed-back laser diodes, so that the center oscillation wavelength is different by 1.6 nanometers between adjacent two of the first to fourth distributed feed-back laser diodes, whereby the absorption edge wavelength of the modulator is also changed by 1.6 nanometers following to the change of the center oscillation wavelength. If the temperature varies in the range of ±8° C., the absorption edge wavelength of the modulator also varies in the range of ±3.2 nanometers. The absorption edge wavelength of the modulator has a temperature dependency of 0.4 nanometers/°C. If the temperature varies by 4° C., then the absorption edge wavelength of the modulator varies 1.6 nanometers. This will be described in more detail with reference to FIG. 4 which illustrative variations in control temperature, absorption edge wavelength of the modulator and detuning over the oscillation wavelength. The detuning corresponds to a subtraction of the absorption edge wavelength of the modulator from the oscillation wavelength. If the controlled temperature of the first distributed feed-back laser diode varies in the range of 20° C.±8° C., then the oscillation wavelength of the first distributed feed-back laser diode varies in the range of 1550±0.8 nanometers, and the absorption edge wavelength of the modulator varies in the range of 1487±3.2 nanometers, whereby the quantity of detuning of the first distributed feed-back laser diode is 63±2.4 nanometers. If the controlled temperature of the second distributed feed-back laser diode varies in the range of 24° C.±8° C., then the oscillation wavelength of the second distributed feed-back laser diode varies in the range of 1551.6±0.8 nanometers, and the absorption edge wavelength of the modulator varies in the range of 1488.6±3.2 nanometers, whereby the quantity of detuning of the second distributed feed-back laser diode is 63±2.4 nanometers. If the controlled temperature of the third distributed feed-back laser diode varies in the range of 28° C.±8° C., then the oscillation wavelength of the third distributed feed-back laser diode varies in the range of 1553.2±0.8 nanometers, and the absorption edge wavelength of the modulator varies in the range of 1490.2±3.2 nanometers, whereby the quantity of detuning of the third distributed feed-back laser diode is 63±2.4 nanometers. If the controlled temperature of the fourth distributed feed-back laser diode varies in the range of 32° C.±8° C., then the oscillation wavelength of the fourth distributed feed-back laser diode varies in the range of 1554.8±0.8 nanometers, and the absorption edge wavelength of the modulator varies in the range of 1491.8±3.2 nanometers, whereby the quantity of detuning of the fourth distributed feed-back laser diode is 63±2.4 nanometers. Namely, the quantity of detuning is uniform to all of the first to fourth distributed feed-back laser diodes.

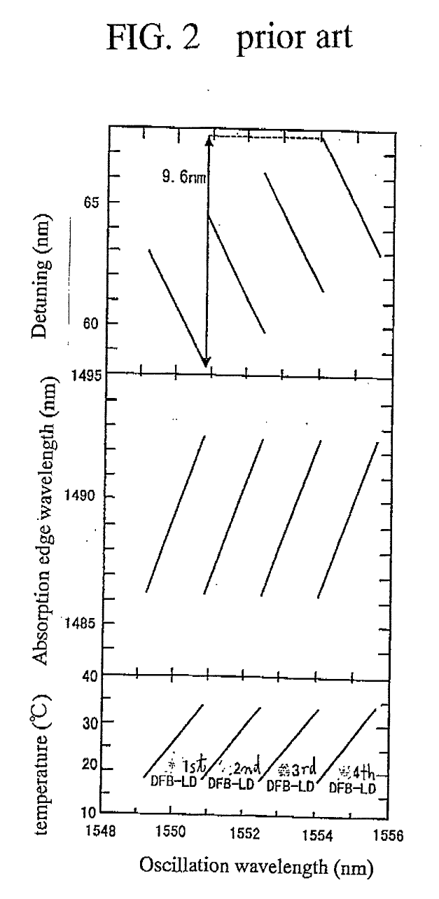

In accordance with the present invention, therefore, a total distribution of the detuning quantity to the first to fourth distributed feed-back laser diodes is limited in a narrow width of 4.8 nanometers as shown in FIG. 4. By contrast, in accordance the prior art, a total distribution of the detuning quantity to the first to fourth distributed feed-back laser diodes is boarded in a wide width of 9.6 nanometers as shown in FIG. 2. The present invention suppresses the total distribution of the detuning quantity into the narrow range, thereby remarkably improving the yield of the device.

The first distributed feed-back laser diode 6 has the diffraction grating pitch of 241.53 nanometers. The first distributed feed-back laser diode 6 has a strained-InGaAsP multiple quantum well structure which has an absorption edge wavelength of 1555 nanometers. The second distributed feed-back laser diode 7 has the diffraction grating pitch of 241.71 nanometers. The second distributed feed-back laser diode 7 has a strained-InGaAsP multiple quantum well structure which has an absorption edge wavelength of 1556.6 nanometers. The third distributed feed-back laser diode 8 has the diffraction grating pitch of 241.90 nanometers. The third distributed feed-back laser diode 8 has a strained-InGaAsP multiple quantum well structure which has an absorption edge wavelength of 1558.2 nanometers. The fourth distributed feed-back laser diode 9 has the diffraction grating pitch of 242.09 nanometers. The fourth distributed feed-back laser diode 9 has a strained-InGaAsP multiple quantum well structure which has an absorption edge wavelength of 1559.8 nanometers. The multi-mode interference multiplexer has a strained-InGaAsP multiple quantum well structure which has an absorption edge wavelength of 1380 nanometers. The semiconductor optical amplifier has a strained-InGaAsP multiple quantum well structure which has an absorption edge wavelength of 1565 nanometers. The modulator has a strained-InGaAsP multiple quantum well structure which has an absorption edge wavelength of 1489.4 nanometers. The those values of the absorption edge wavelengths are given at 26° C.

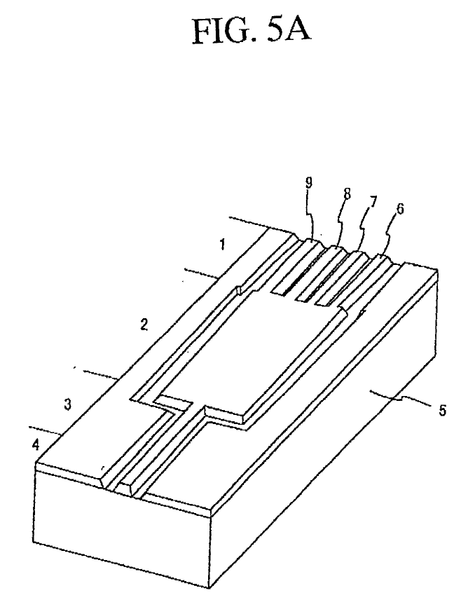

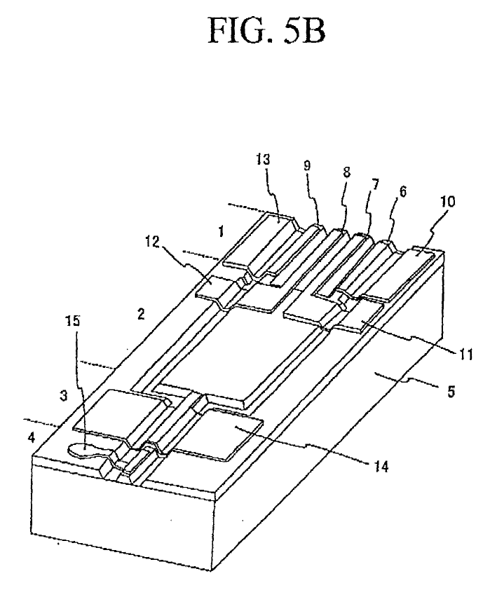

The description will focus on sequential fabrication processes for the above novel wavelength-selective light emitting device of FIG. 3. FIGS. 5A and 5B are schematic perspective views illustrative of novel wavelength-selective light emitting devices in sequential steps involved in a novel fabrication method in a first embodiment in accordance with the present invention.

A weighted-dose allocation for variable-pitch electron beam corrugation is utilized to form first to fourth diffraction gratings over an n-InP substrate 5, wherein the first diffraction grating has a first grating pitch of 241.53 nanometers, the second diffraction grating has a second grating pitch of 241.71 nanometers, the third diffraction grating has a third grating pitch of 241.90 nanometers, and the fourth diffraction grating has a fourth grating pitch of 242.09 nanometers. A metal organic vapor phase epitaxy method is carried out to selectively form first to fourth strained InGaAsP multiple quantum well structures over the first to four diffraction gratings, respectively and concurrently form fifth to seventh strained InGaAsP multiple quantum well structures. The first strained-InGaAsP multiple quantum well structure for the first distributed feed-back laser diode 6 has an absorption edge wavelength of 1555 nanometers. The second strained-InGaAsP multiple quantum well structure for the second distributed feed-back laser diode 7 has an absorption edge wavelength of 1556.6 nanometers. The third strained-InGabsP multiple quantum well structure for the third distributed feed-back laser diode 8 has an absorption edge wavelength of 1558.2 nanometers. The fourth strained-InGaAsP multiple quantum well structure for the fourth distributed feed-back laser diode 9 has an absorption edge wavelength of 1559.8 nanometers. The fifth strained-InGaAsP multiple quantum well structure for the multi-mode interference multiplexer has an absorption edge wavelength of 1380 nanometers. The sixth strained-InGaAsP multiple quantum well structure for the semiconductor optical amplifier has an absorption edge wavelength of 1565 nanometers. The seventh strained-InGaAsP multiple quantum well structure for the modulator has an absorption edge wavelength of 1489.4 nanometers.

As a result, the first distributed feed-back laser diode 6 has a strained-InGaAsP multiple quantum well structure which has an absorption edge wavelength of 1555 nanometers. The second distributed feed-back laser diode 7 has a strained-InGaAsP multiple quantum well structure which has an absorption edge wavelength of 1556.6 nanometers. The third distributed feed-back laser diode 8 has a strained-InGaAsP multiple quantum well structure which has an absorption edge wavelength of 1558.2 nanometers. The fourth distributed feed-back laser diode 9 has a strained-InGaAsP multiple quantum well structure which has an absorption edge wavelength of 1559.8 nanometers. The multi-mode interference multiplexer has a strained-InGasP multiple quantum well structure which has an absorption edge wavelength of 1380 nanometers. The semiconductor optical amplifier has a strained-InGaAsP multiple quantum well structure which has an absorption edge wavelength of 1565 nanometers. The modulator has a strained-InGaAsP multiple quantum well structure which has an absorption edge wavelength of 1489.4 nanometers. The those values of the absorption edge wavelengths are given at 26° C. The first distributed feed-back laser diode 6 has the diffraction grating pitch of 241.53 nanometers. The second distributed feed-back laser diode 7 has the diffraction grating pitch of 241.71 nanometers. The third distributed feed-back laser diode 8 has the diffraction grating pitch of 241.90 nanometers. The fourth distributed feed-back laser diode 9 has the diffraction grating pitch of 242.09 nanometers.

With reference to FIG. 5A, an InP burying layer is entirely grown over the substrate 5. A contact layer comprising an InGaAsP layer and an InGaAs layer is entirely formed as a top layer. The contact layer is selectively removed from a window region of the modulator, a boundary region between the modulator and the semiconductor optical amplifier and the multi-mode interference multiplexer section. A silicon dioxide film is then entirely formed.

With reference to FIG. 5B, openings of the silicon dioxide film are selectively formed over top surfaces of the ridged portions which correspond to the first distributed feed-back laser diode 6, the second distributed feed-back laser diode 7, the third distributed feed-back laser diode 8, and the fourth distributed feed-back laser diode 9, the semiconductor optical amplifier and the modulator. A first distributed feed-back laser diode electrode 10 is formed which is in contact via the opening of the silicon dioxide film with the top surface of the ridged portion corresponding to the first distributed feed-back laser diode 6. A second distributed feed-back laser diode electrode 11 is formed which is in contact via the opening of the silicon dioxide film with the top surface of the ridged portion corresponding to the second distributed feed-back laser diode 7. A third distributed feed-back laser diode electrode 12 is formed which is in contact via the opening of the silicon dioxide film with the top surface of the ridged portion corresponding to the third distributed feed-back laser diode 8. A fourth distributed feed-back laser diode electrode 13 is formed which is in contact via the opening of the silicon dioxide film with the top surface of the ridged portion corresponding to the fourth distributed feed-back laser diode 9. A semiconductor optical amplifier electrode 14 is formed which is in contact via the opening of the silicon dioxide film with the top surface of the ridged portion corresponding to the semiconductor optical amplifier. A modulator electrode 15 is formed which is in contact via the opening of the silicon dioxide film with the top surface of the ridged portion corresponding to the modulator.

With reference back to FIG. 3, a common electrode 16 is formed on a bottom surface of the substrate 5. The wafer is then cleaved to form first and second facets, the first facet is then coated with an anti-reflective coating film 17.

In the above described embodiment, the number of arrays is four. The present invention is applicable to any number of the arrays. In the above described embodiment, the temperature control range is ±8° C. for each of the distributed feed-back laser diodes, so that the difference in the center oscillation wavelength-between adjacent two of the distributed feed-back laser diodes is 1.6 nanometers. It is of course possible to change the temperature control range. If, for example, the temperature control range is ±16° C. for each of the distributed feed-back laser diodes, then the difference in the center oscillation wavelength between adjacent two of the distributed feed-back laser diodes is 3.2 nanometers, and the difference in center temperature of the controlled temperature range between adjacent two of the distributed feed-back laser diodes is 8° C., whereby the detuning quantity is constant.

In accordance with the above embodiment, the modulator 4 receives the similar temperature control to the distributed feed-back laser diode array. It is possible as a modification that the first to fourth distributed feed-back laser diodes are temperature-controlled at a fixed temperature of 26° C., whilst the modulator 4 is so temperature-controlled that a center temperature is increased by 4° C. every when the first distributed feed-back laser diode is switched to the second distributed feed-back laser diode, and when the second distributed feed-back laser diode is switched to the third distributed feed-back laser diode, and when the third distributed feed-back laser diode is switched to the fourth distributed feed-back laser diode. In this case, the temperature control range to the first to fourth distributed feed-back laser diodes is similar to the prior art of FIG. 2. The first to fourth diffraction grating pitches of the first to fourth distributed feed-back laser diodes are 241.43 nanometers, 241.68 nanometers, 241.93 nanometers, and 242.18 nanometers, respectively.

In the above embodiment, the distributed feed-back laser diode section 1 is bounded with the multi-mode interference multiplexer section 2. The present invention is applicable to another wavelength-selective light emitting device having a different structure, wherein a curved waveguide is interposed between the distributed feed-back laser diode section 1 and the multi-mode interference multiplexer section 2.

In accordance with the first embodiment of the present invention, it is important that the variation of the wavelength detuning is small and within an allowable narrow range in temperature control and in switching the distributed feed-back laser diodes. The variation of the wavelength detuning is not zero.

SECOND EMBODIMENT:

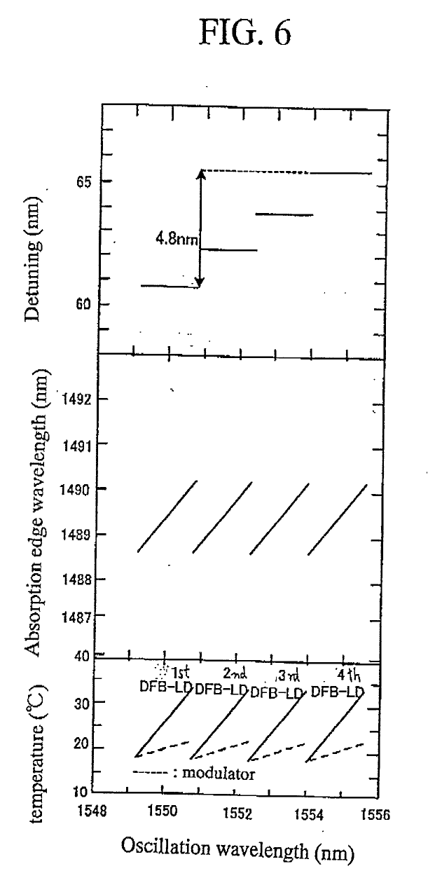

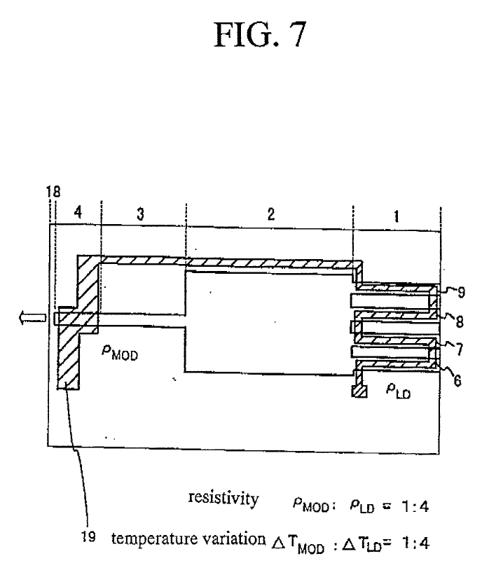

A second embodiment according to the present invention will be described in detail with reference to the drawings. FIG. 6 is a diagram illustrative of variations in temperature, absorption edge wavelength of the modulator and detuning over wavelength in order to explain a second novel method of controlling the oscillation wavelength of the laser diode and the absorption edge wavelength of the modulator of the novel modulator-integrated wavelength-selective light emitting device in a second embodiment in accordance with the present invention. FIG. 7 is a plane view illustrative of a novel modulator-integrated wavelength-selective light emitting device having a multi-mode interference multiplexer and four arrays of distributed feed-back laser diodes as well as a heating resistance line in a second embodiment in accordance with the present invention.

The oscillation wavelength of the distributed feed-back laser diode has a temperature-dependency of about 0.1 nanometer/°C. The absorption edge wavelength of the modulator has a temperature-dependency of about 0.4 nanometers/°C. Thus, if the ratio in temperature variation of the distributed feed-back laser diode section 1 to the modulator section 4 is 4:1, then no variation in detuning depending on the temperature variation is caused.

The temperature dependency of the oscillation wavelength of the distributed feed-back laser diode and the temperature dependency of the absorption edge wavelength of the modulator depend on the composition of the active layer and also on the layered structure of the active layer. The temperature dependency of the oscillation wavelength of the distributed feed-back laser diode and the temperature dependency of the absorption edge wavelength of the modulator may vary by about a few percents due to errors on the manufacturing processes. In this case, it is effective that the ratio in temperature variation of the distributed feed-back laser diode to the modulator is so decided as that the temperature-variation of the oscillation wavelength of the distributed feed-back laser diode is equal to the temperature-variation of the absorption edge wavelength of the modulator

In order to realize that the distributed feed-back laser diode section 1 and the modulator section 4 are controlled at different temperatures from each other, it is effective that a chip is temperature-controlled by Peltier device and further heat resistive lines 19 are respectively provided on the distributed feed-back laser diode section 1 and the modulator section 4, wherein the heat resistive lines 19 are different in resistivity between the distributed feed-back laser diode section 1 and the modulator section 4.

For forming the second novel wavelength-selective light emitting device of this second embodiment, the same fabrication processes as in the first embodiment shown in FIGS. 5A and 5B are carried out before a further silicon dioxide film is entirely formed. After the silicon dioxide film is entirely formed, then heat resistive lines 19 made of Pt are formed as shown in FIG. 7. The silicon dioxide film selectively removed from bonding pads of the first distributed feed-back laser diode electrode 10, the second distributed feed-back laser diode electrode 11, the third distributed feed-back laser diode electrode 12, the fourth distributed feed-back laser diode electrode 13, the semiconductor optical amplifier electrode 14, and the modulator electrode 15. Further, a common electrode is formed on the bottom surface of the substrate. The chip is cleaved to form first and second facets. The first facet is then coated with an anti-reflective coating film.

The heat resistive lines 19 are higher in resistivity over the distributed feed-back laser diode section 1 and lower in resistivity over the modulator section 4, so that a ratio in temperature variation of the multiple quantum well structure of the distributed feed-back laser diode to the multiple quantum well structure of the modulator is 4:1. If the heat resistive lines 19 over the distributed feed-back laser diode and the modulator are the same as each other in heat resistance, then a ratio in resistance per a unit length of the beat resistive line 19 over the distributed feed-back laser diode to the heat resistive line 19 over the modulator is set at 4:1. In order to obtain the 4:1 ratio in resistance per a unit length of the heat resistive line 19 over the distributed feed-back laser diode to the heat resistive line 19 over the modulator, it is possible that a ratio in sectioned area of the heat resistive line 19 over the distributed feed-back laser diode to the heat resistive line 19 over the modulator is 4:1. In order to obtain the 4:1 ratio in sectioned area, it is possible that a ratio in width of the heat resistive line 19 over the distributed feed-back laser diode to the heat resistive line 19 over the modulator is 4:1. It is also possible that a ratio in thickness of the heat resistive line 19 over the distributed feed-back laser diode to the heat resistive line 19 over the modulator is 4:1. Alternatively, in order to obtain the 4:1 ratio in resistance per a unit length of the heat resistive line 19 over the distributed feed-back laser diode to the heat resistive line 19 over the modulator, it is possible that the heat resistive line 19 over the distributed feed-back laser diode is different in material from the heat resistive line 19 over the modulator.

With reference to FIG. 6, the device temperature is maintained at 18° C. by the Peltier device, and a current is applied to the heat resistive line 19 to generate a heat, so that the distributed feed-back laser diode section 1 is maintained at 26° C.±8° C., whilst the modulator section 1 is maintained at 20° C.±2° C.

The temperature control range for the distributed feed-back laser diode is the same as in the prior art shown in FIG. 2. Thus, the first to fourth diffraction grating pitches of the first to fourth distributed feed-back laser diodes are 241.43 nanometers, 241.68 nanometers, 241.93 nanometers, and 242.18 nanometers. The absorption edge wavelength of the modulator is 1489.4 nanometers which corresponds to a subtraction of the optimum detuning value of 63 nanometers from a center value of 1552.4 nanometers of the total oscillation wavelength. Since the control center temperature of the modulator is 20° C., then the absorption edge wavelength of the modulator is adjusted at 1489.4 nanometers at 20° C. When the modulator is heated at 20° C.±2° C., then the absorption edge wavelength of the modulator is 1489.4±0.8 nanometers. The detuning quantity for the first distributed feed-back laser diode is constant at 60.6 nanometers. The detuning quantity for the second distributed feed-back laser diode is constant at 62.2 nanometers. The detuning quantity for the third distributed feed-back laser diode is constant at 63.8 nanometers. The detuning quantity for the fourth distributed feed-back laser diode is constant at 65.4 nanometers. The total detuning variation is within the narrow range of 4.8 nanometers to achieve the object of the present invention. The variable temperature ranges of the distributed feed-back laser diodes and the modulator are narrower than in the first embodiment. This means that the variation in power of the wavelength selection and the variation in the extinction ratio are further reduced.

In the above second embodiment, a single resistive line extends in series over both the distributed feed-back laser diode section and the modulator section. It is also possible as a modification that separate resistive lines are separately provided for the distributed feed-back laser diode section and the modulator section, wherein the current values applied to the separate resistive lines are set so that the temperature variation ratio of the distributed feed-back laser diode section to the modulator section is 4:1, whereby no detuning variation depending on the temperature variation is caused.

It is also possible to combine the features of the novel methods of the first and second embodiments. In the first embodiment, the detuning variation due to switching the distributed feed-back laser diodes is suppressed. In the second embodiment, no detuning variation is cased upon temperature variation of the distributed feed-back laser diodes. In combination, in the all wavelength range, the detuning is made constant.

THIRD EMBODIMENT:

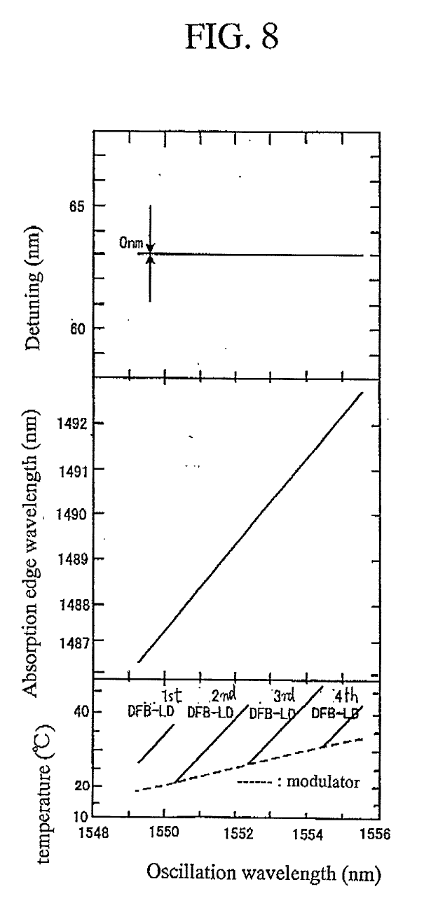

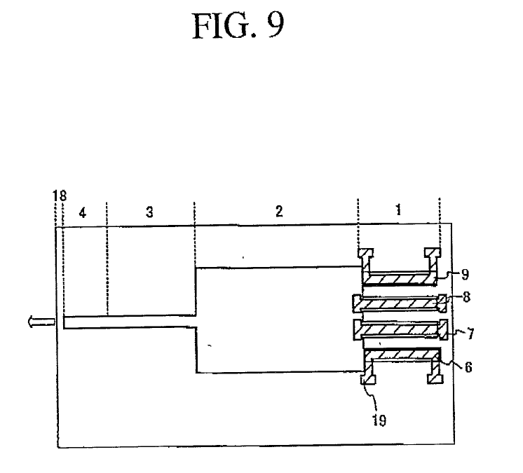

A third embodiment of the present invention will be described with reference to the drawings. In the all wavelength range, the detuning may be made constant. The entire part of the chip is temperature-adjusted by the Peltier device and further the resistive line is provided over the distributed feed-back laser diode section 1, so that the distributed feed-back laser diode section 1 and the modulator 4 are controlled at different temperatures. FIG. 8 is a diagram illustrative of variations in temperature, absorption edge wavelength of the modulator and detuning over wavelength in order to explain a third novel method of controlling the oscillation wavelength of the laser diode and the absorption edge wavelength of the modulator of the novel modulator-integrated wavelength-selective light emitting device in a third embodiment in accordance with the present invention. FIG. 9 is a plane view illustrative of a novel modulator-integrated wavelength-selective light emitting device having a multi-mode interference multiplexer and four arrays of distributed feed-back laser diodes as well as a heating resistance line in a third embodiment in accordance with the present invention.

The entire part of the chip is temperature-adjusted by the Peltier device and further the resistive line 19 is provided over the distributed feed-back laser diode section 1, so that the distributed feed-back laser diode section 1 and the modulator 4 are controlled at different temperatures.

The temperature of the distributed feed-back laser diode section 1 is controlled in the range of 26° C.±8° C. The oscillation wavelength of the first distributed feed-back laser diode is 1549.2±0.8 nanometers. The oscillation wavelength of the second distributed feed-back laser diode is 1550.8±0.8 nanometers. The oscillation wavelength of the third distributed feed-back laser diode is 1552.4±0.8 nanometers. The oscillation wavelength of the fourth distributed feed-back laser diode is 1554.0±0.8 nanometers. The diffraction grating pitch of the first distributed feed-back laser diode is 241.31 nanometers. The diffraction grating pitch of the second distributed feed-back laser diode is 241.56 nanometers. The diffraction grating pitch of the third distributed feed-back laser diode is 241.81 nanometers. The diffraction grating pitch of the fourth distributed feed-back laser diode is 242.06 nanometers. If the temperature of the modulator 4 is controlled in the range of 26° C.±8° C., then the absorption edge wavelength of the modulator is 1489.4±3.2 nanometers.

The device is temperature-controlled by the Peltier device in the range of 18° C. to 34° C. The distributed feedback laser diode section is further temperature-controlled by the resistive line 19 in addition to the Peltier device. The first distributed feed-back laser diode is maintained in the range of 26° C. to 36.7° C. The second distributed feed-back laser diode is maintained in the range of 20.7° C. to 42° C. The third distributed feed-back laser diode is maintained in the range of 26° C. to 47.3° C. The fourth distributed feed-back laser diode is maintained in the range of 31.3° C. to 42° C. The first distributed feed-back laser diode is higher in temperature by 8° C. to 16° C. than the modulator. This temperature difference may be compensated by applying a current to the resistive line 19. The second distributed feed-back laser diode is higher in temperature by 0° C. to 16° C. than the modulator. This temperature difference may be compensated by applying a current to the resistive line 19. The third distributed feed-back laser diode is higher in temperature by 0° C. to 16° C. than the modulator. This temperature difference may be compensated by applying a current to the resistive line 19. The fourth distributed feed-back laser diode is higher in temperature by 0° C. to 8° C. than the modulator. This temperature difference may be compensated by applying a current to the resistive line 19.

The oscillation wavelength of the first distributed feed-back laser diode is in the range of 1549.2 nanometers to 1550.3 nanometers. The oscillation wavelength of the second distributed feed-back laser diode is in the range of 1550.3 nanometers to 1552.4 nanometers, The oscillation wavelength of the third distributed feed-back laser diode is in the range of 1552.4 nanometers to 1554.5 nanometers. The oscillation wavelength of the fourth distributed feed-back laser diode is in the range of 1554.5 nanometers to 1555.6 nanometers. In total, the oscillation wavelengths of the first to fourth distributed feed-back laser diodes cover the range of 1549.2 nanometers to 1555.6 nanometers. The absorption edge wavelength of the modulator is ranged from 1486.2 nanometers to 1492.6 nanometers. The absorption edge wavelength of the modulator completely follows to the oscillation wavelength of the distributed feed-back laser diodes. This means that no detuning variation is caused in the entire wavelength range.

No detuning variation allows the higher level manufacturing yield as the single oscillation wavelength modulator-integrated distributed feed-back laser diode.

Another method of fixing the detuning quantity over the entire wavelength range is that the chip is temperature-adjusted by the Peltier device and the resistive line is provided on the modulator section. This method will be described as the following embodiment.

FOURTH EMBODIMENT:

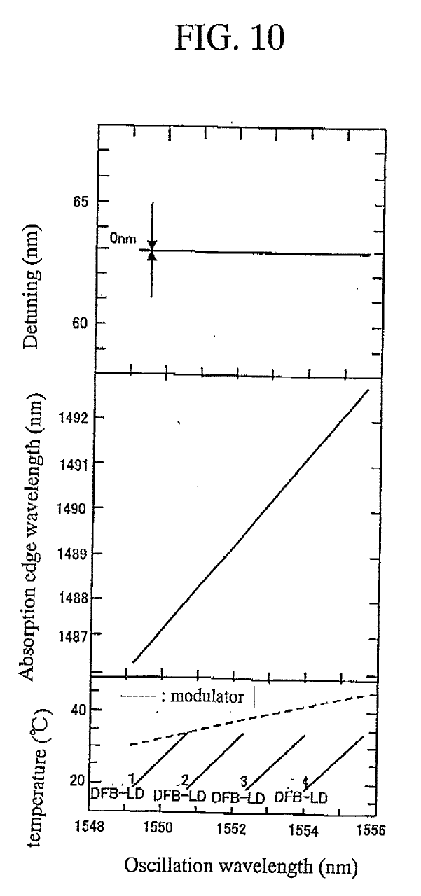

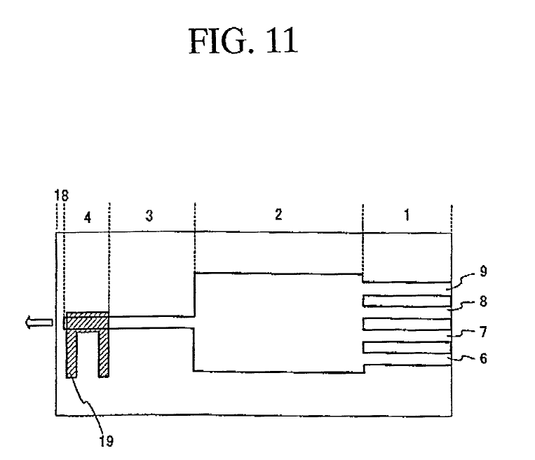

A fourth embodiment of the present invention will be described with reference to the drawings. In the all wavelength range, the detuning may be made constant. The entire part of the chip is temperature-adjusted by the Peltier device and further the resistive line is provided over the modulator section 4, so that the distributed feed-back laser diode section 1 and the modulator 4 are controlled at different temperatures. FIG. 10 is a diagram illustrative of variations in temperature, absorption edge wavelength of the modulator and detuning over wavelength in order to explain a fourth novel method of controlling the oscillation wavelength of the laser diode and the absorption edge wavelength of the modulator of the novel modulator-integrated wavelength-selective light emitting device in a fourth embodiment in accordance with the present invention. FIG. 11 is a plane view illustrative of a novel modulator-integrated wavelength-selective light emitting device having a multi-mode interference multiplexer and four arrays of distributed feed-back laser diodes as well as heating resistance line in a fourth embodiment in accordance with the present invention.

The entire part of the chip is temperature-adjusted by the Peltier device and further the resistive line 19 is provided over the modulator section 4, so that the distributed feed-back laser diode section 1 and the modulator 4 are controlled at different temperatures.

The temperature of the distributed feed-back laser diode section 1 is controlled the same as in the prior art of FIG. 2. The diffraction grating pitch of the first distributed feed-back laser diode is 241.43 nanometers. The diffraction grating pitch of the second distributed feed-back laser diode is 241.68 nanometers. The diffraction grating pitch of the third distributed feed-back laser diode is 241.93 nanometers. The diffraction grating pitch of the fourth distributed feed-back laser diode is 242.18 nanometers. If the temperature of the modulator 4 is controlled in the range of 26° C.±8° C., then the absorption edge wavelength of the modulator is 1484.6±3.2 nanometers.

The device is temperature-controlled by the Peltier device in the range of 26° C.±8° C. The modulator section 4 is further temperature-controlled by the resistive line 19 in addition to the Peltier device. The first modulator is maintained in the range of 32° C.±2° C. The second modulator is maintained in the range of 36° C.±2° C. The third modulator is maintained in the range of 40° C.±2° C. The fourth modulator is maintained in the range of 44° C.±2° C. The first modulator is higher in temperature by 6° C.±6° C. than the first distributed feed-back laser diode. This temperature difference may be compensated by applying a current to the resistive line 19. The second modulator is higher in temperature by 10° C.±6° C. than the second distributed feed-back laser diode, This temperature difference may be compensated by applying a current to the resistive line 19. The third modulator is higher in temperature by 14° C.±6° C. than the third distributed feed-back laser diode. This temperature difference may be compensated by applying a current to the resistive line 19. The fourth modulator is higher in temperature by 18° C.±6° C. than the fourth distributed feed-back laser diode. This temperature difference may be compensated by applying a current to the resistive line 19.

The oscillation wavelength of the first distributed feed-back laser diode is 1550.2±0.8 nanometers. The oscillation wavelength of the second distributed feed-back laser diode is 1551.6±0.8 nanometers. The oscillation wavelength of the third distributed feed-back laser diode is 1553.2±0.8 nanometers. The oscillation wavelength of the fourth distributed feed-back laser diode is 1554.8±0.8 nanometers. In total, the oscillation wavelengths of the first to fourth distributed feed-back laser diodes cover the range of 1549.2 nanometers to 1555.6 nanomneters. The absorption edge wavelength of the first modulator is ranged from 1487±0.8 nanometers. The absorption edge wavelength of the second modulator is ranged from 1488.6±0.8 nanometers. The absorption edge wavelength of the third modulator is ranged from 1490.2±0.8 nanometers. The absorption edge wavelength of the fourth modulator is ranged from 1491.8±0.8 nanometers. The absorption edge wavelength of the modulator completely follows to the oscillation wavelength of the distributed feed-back laser diodes. This means that no detuning variation is caused in the entire wavelength range,

No detuning variation allows the higher level manufacturing yield as the single oscillation wavelength modulator-integrated distributed feed-back laser diode.

FIFTH EMBODIMENT:

A fifth embodiment of the present invention will be described. In the above first to fourth embodiments. The inter-relationship between the oscillation wavelength of the distributed feed-back laser diode and the absorption edge wavelength of the modulator. Notwithstanding, the multi-mode interference multiplexer and the semiconductor optical amplifier have optimum operational temperatures in association with the oscillation wavelength of the distributed feed-back laser diodes.

In case of 1×NMMI (multi-mode interference), the relationship of an optimum MMI length=MMI equivalent refraction index×(effective MMI width)² /(DFB=LD oscillation wavelength×N). In case of MMI, the conditions are different from the optimum MMI length, the excess loss is generated. The excess loss is not so large based on the variation in oscillation wavelength and the variation in equivalent refraction index of the multi-mode interference multiplexer, for which reason it is optional to do the optimum temperature control.

The optimum conditions are as follows. The multi-mode interference multiplexer is temperature-controlled every when the distributed feed-back laser diode is temperature-controlled. The temperature variation of the oscillation wavelength is caused by the temperature variation in the refractive index, for which reason the equivalent refractive index of the multi-mode interference multiplexer varies almost similarly.

For the semiconductor optical amplifier, it is preferable that the gain peak wavelength of the semiconductor optical amplifier varies following to the oscillation wavelength of the distributed feedback laser diode. The temperature dependency of the gain peak wavelength of the semiconductor optical amplifier is 0.4 nanometers/°C., similarly to the temperature dependency of the absorption edge wavelength of the modulator. For this reason, the temperature variation of the semiconductor optical amplifier is associated with the modulator, so that no variation in gain of the semiconductor optical amplifier is caused when the wavelength is switched. The gain of the semiconductor optical amplifier may somewhat be compensated by adjusting the current applied to the semiconductor optical amplifier, For this reason the above temperature control is optional. The distributed feed-back laser diode and the multi-mode interference multiplexer are preferably controlled at the same temperature, wherein the distributed feed-back laser diode and the multi-mode interference multiplexer are subjected to the temperature dependency of the equivalent refractive index. The modulator and the semiconductor optical amplifier are also preferably controlled at the same temperature, wherein the modulator and the semiconductor optical amplifier are subjected to the temperature dependency of the absorption edge wavelength.

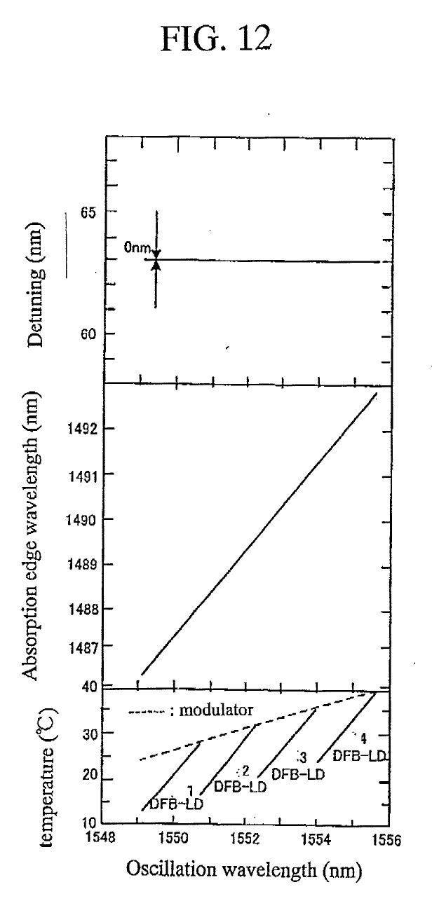

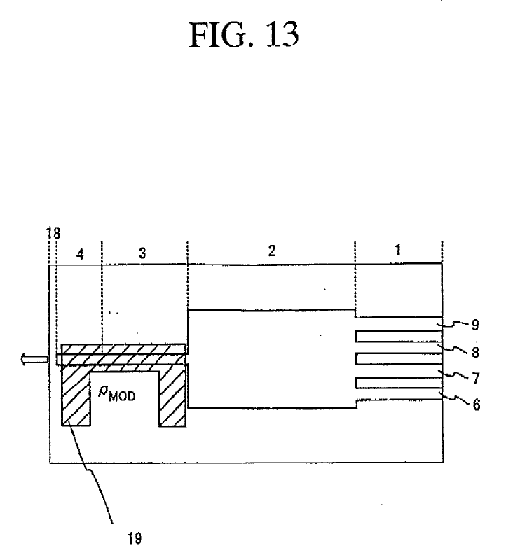

FIG. 12 is a diagram illustrative of variations in temperature, absorption edge wavelength of the modulator and detuning over wavelength in order to explain a fifth novel method of controlling the oscillation wavelength of the laser diode and the absorption edge wavelength of the modulator of the novel modulator-integrated wavelength-selective light emitting device in a fifth embodiment in accordance with the present invention. FIG. 13 is a plane view illustrative of a novel modulator-integrated wavelength-selective light emitting device having a multi-mode interference multiplexer and four arrays of distributed feed-back laser diodes as well as a heating resistance line in a fifth embodiment in accordance with the present invention.

The multi-mode interference multiplexer and the distributed feed-back laser diodes are controlled at the same temperature by the Peltier device. The semiconductor optical amplifier and the modulator are controlled at the same temperature by the Peltier device in combination with the resistive line 19. Since the resistive line 19 is not provided over the distributed feed-back laser diode section 1 and the multi-mode interference multiplexer section 2, the distributed feed-back laser diode section 1 and the multi-mode interference multiplexer section 2 are subjected to the temperature control by the Peltier device. The first distributed feed-back laser diode is temperature-controlled in the range of 2° C.±8° C. The second distributed feed-back laser diode is temperature-controlled in the range of 24° C.±8° C. The third distributed feed-back laser diode is temperature-controlled in the range of 28° C.±8° C. The fourth distributed feed-back laser diode is temperature-controlled in the range of 32° C.±8° C.

The first modulator is also temperature-controlled in the range of 26° C.±8° C. The second modulator is also temperature-controlled in the range of 30° C.±8° C. The third modulator is also temperature-controlled in the range of 34° C.±8° C. The fourth modulator is also temperature-controlled in the range of 38° C.±8° C. The first modulator is higher in temperature by 6° C.±6° C. than the first distributed feed-back laser diode. This temperature difference may be compensated by applying a current to the resistive line 19. The second modulator is higher in temperature by 6° C.±6° C. than the second distributed feed-back laser diode. This temperature difference may be compensated by applying a current to the resistive line 19. The third modulator is higher in temperature by 6° C.±6° C. than the third distributed feed-back laser diode. This temperature difference may be compensated by applying a current to the resistive line 19. The fourth modulator is higher in temperature by 6° C.±8° C. than the fourth distributed feed-back laser diode. This temperature difference may be compensated by applying a current to the resistive line 19. The application of the current to the resistive line 19 enables the absorption edge wavelength of the modulator to follow to the oscillation wavelength, whereby no detuning variation is caused in the entire wavelength range.

No detuning variation allows the higher level manufacturing yield as the single oscillation wavelength modulator-integrated distributed feed-back laser diode.

SIXTH EMBODIMENT:

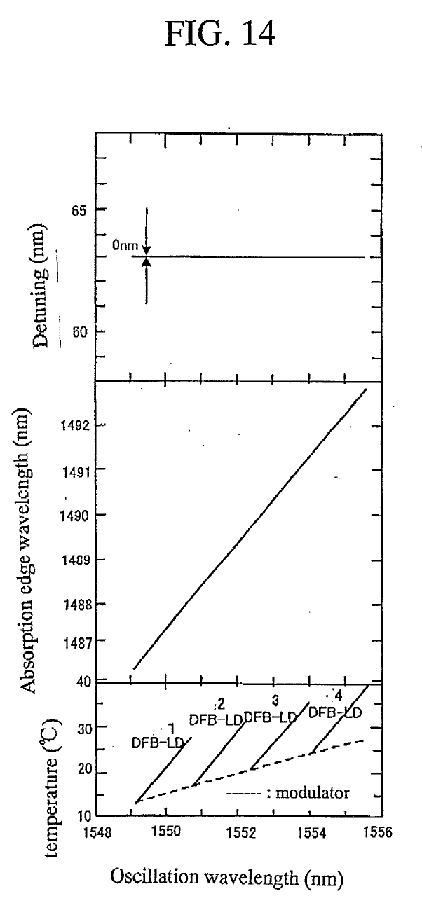

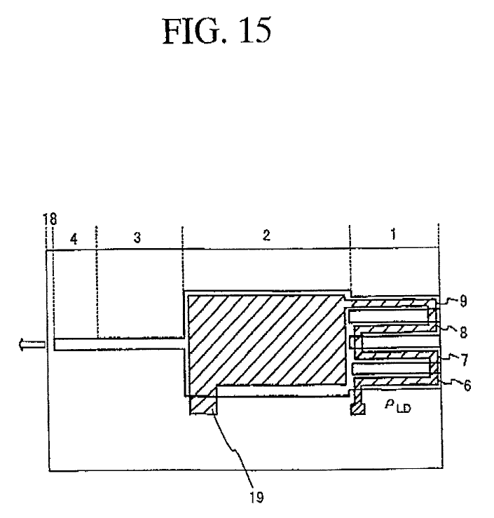

A sixth embodiment of the present invention will be described. FIG. 14 is a diagram illustrative of variations in temperature, absorption edge wavelength of the modulator and detuning over wavelength in order to explain a sixth novel method of controlling the oscillation wavelength of the laser diode and the absorption edge wavelength of the modulator of the novel modulator-integrated wavelength-selective light emitting device in a sixth embodiment in accordance with the present invention. FIG. 15 is a plane view illustrative of a novel modulator-integrated wavelength-selective light emitting device having a multi-mode interference multiplexer and four arrays of distributed feed-back laser diodes as well as a heating resistance line in a sixth embodiment in accordance with the present invention.

The multi-mode interference multiplexer and the distributed feed-back laser diodes are controlled at the same temperature by the Peltier device in combination with the resistive line 19. The semiconductor optical amplifier and the modulator are controlled at the same temperature by the Peltier device, As the oscillation wavelength is changed from 1549.2 nanometers to 1555.6 nanometers, then the temperature variable range by the Peltier device is from 12° C. to 28° C., so that the absorption edge wavelength of the modulator varies following to the variation of the oscillation wavelength. The first distributed feed-back laser diode is temperature-controlled in the range of 20° C.±8° C. The second distributed feed-back laser diode is temperature-controlled in the range of 24° C.±8° C. The third distributed feed-back laser diode is temperature-controlled in the range of 28° C.±8° C. The fourth distributed feed-back laser diode is temperature-controlled in the range of 32° C.±8° C.

The first modulator is also temperature-controlled in the range of 14° C.±8° C. The second modulator is also temperature-controlled in the range of 18° C.±8° C. The third modulator is also temperature-controlled in the range of 22° C.8° C. The fourth modulator is also temperature-controlled in the range of 26° C.±8° C. The first modulator is lower in temperature by 6° C.±8° C. than the first distributed feed-back laser diode. This temperature difference may be compensated by applying a current to the resistive line 19. The second modulator is lower in temperature by 6° C.±6° C. than the second distributed feed-back laser diode. This temperature difference may be compensated by applying a current to the resistive line 19. The third modulator is lower in temperature by 6° C.±6° C. than the third distributed feed-back laser diode. This temperature difference may be compensated by applying a current to the resistive line 19. The fourth modulator is lower in temperature by 6° C.±6° C. than the fourth distributed feed-back laser diode. This temperature difference may be compensated by applying a current to the resistive line 19. The application of the current to the resistive line 19 enables the absorption edge wavelength of the modulator to follow to the oscillation wavelength, whereby no detuning variation is caused in the entire wavelength range.

No detuning variation allows the higher level manufacturing yield as the single oscillation wavelength modulator-integrated distributed feed-back laser diode.

In this sixth embodiment, the temperature variable range of the modulator is lower than that of the fifth embodiment. For this reason, the abrupt absorption spectrum of the modulator is obtained. Since the extinction ratio depends on the voltage level, the wider manufacturing margin is obtained than that of the fifth embodiment.

SEVENTH EMBODIMENT:

A seventh embodiment of the present invention will be described. It is possible to make the detuning quantity constant over the entire wavelength range if the single distributed feed-back laser diode is provided and no multiplexer is provided. The chip is temperature-controlled by the Peltier device and the current is applied to the resistive layer extending over the distributed feed-back laser diode section 1, so that the distributed feed-back laser diode section 1 and the modulator section 4 are controlled at the different temperatures.

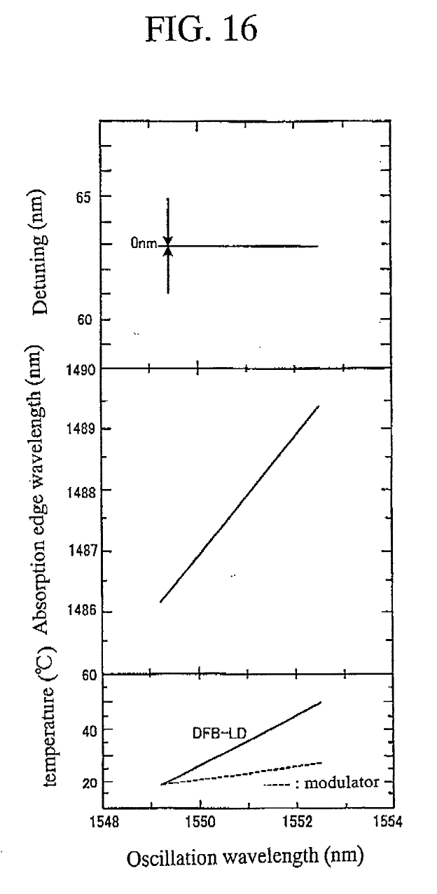

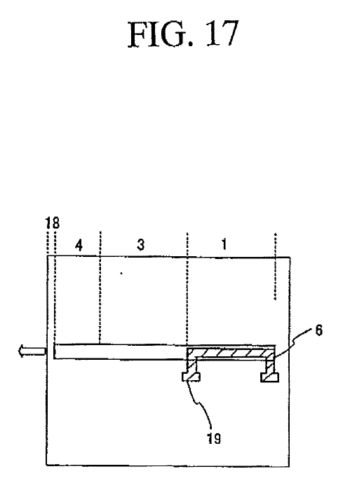

FIG. 16 is a diagram illustrative of variations in temperature, absorption edge wavelength of the modulator and detuning over wavelength in order to explain a seventh novel method of controlling the oscillation wavelength of the laser diode and the absorption edge wavelength of the modulator of the novel modulator-integrated wavelength-selective light emitting device in a seventh embodiment in accordance with the present invention. FIG. 17 is a plane view illustrative of a novel modulator-integrated wavelength-selective light emitting device having a multi-mode interference multiplexer and four arrays of distributed feed-back laser diodes as well as a heating resistance line in a seventh embodiment in accordance with the present invention.

The chip is temperature-controlled by the Peltier device and the current is applied to the resistive layer extending over the distributed feed-back laser diode section 1, so that the distributed feed-back laser diode section 1 and the modulator section 4 are controlled at the different temperatures.

If the distributed feed-back laser diode is temperature-controlled in the range of 26±8° C., then the oscillation wavelength varies in the range of 1550±0.8 nanometers. The diffraction grating is decided on the basis of the temperature control and the wavelength control. The diffraction grating is 241.43 nanometers which is equal to that of the first distributed feed-back laser diode in the prior art shown in FIG. 2. The modulator is temperature-controlled in the range of 26±8° C., the absorption edge wavelength varies in the range of 1489.4±3.2 nanometers.

The modulator is temperature-controlled by the Peltier device in the range of 22±4° C. The distributed feed-back laser diode is temperature-controlled by the Peltier device in combination with the resistive line 19 in the range of 34±16° C. The distributed feed-back laser diode is higher in temperature by 12±12° C. than the modulator This temperature difference may be compensated by applying the current to the resistive line 19.

The oscillation wavelength varies in the range of 1550.8±1.6 nanometers. The absorption edge wavelength varies in the range of 1487.8±1.6 nanometers. The absorption edge wavelength of the modulator follows to the oscillation wavelength. No detuning variation is caused in the entire wavelength range.

In this embodiment, the semiconductor optical amplifier is interposed between the distributed feed-back laser diode and the modulator. This semiconductor optical amplifier is structurally essential for the device of this embodiment for the following first and second reasons.

The first reason is that the semiconductor optical amplifier compensates the deterioration of the optical output characteristics due to the temperature increase of the distributed feed-back laser diode. Since the single distributed feed-back laser diode is provided, it is necessary to increase the temperature variable range of the single distributed feed-back laser diode for obtaining the same wide wavelength variable range as in case of the plural distributed feed-back laser diodes are provided. The increase in the temperature variable range needs the temperature increase which results in a large deterioration in the optical output characteristic of the distributed feed-back laser diode. In order to compensate the deterioration in the optical output characteristic, the semiconductor optical amplifier is positioned on the follower stage to the distributed feed-back laser diode.

The second reason is to avoid the deterioration in characteristics of the modulator due to the temperature increase. If the semiconductor optical amplifier is not provided, then the heat is generated from the resistive line 19 over the distributed feed-back laser diode section 1 and then this heat is transferred to the modulator, whereby the temperature increase of the modulator is caused, resulting in deterioration in the performance of the modulator. In accordance with this seventh embodiment, however, the semiconductor optical amplifier interposed between the distributed feed-back laser diode section 1 and the modulator section 4 makes the modulator section 4 distanced from the distributed feed-back laser diode section 1 and the modulator section 4 is free from the influence of the heat generation from the resistive line 19 over the distributed feed-back laser diode section 1.

In the above third to seventh embodiments, no detuning variation is caused independent from the oscillation wavelength. Notwithstanding, the detuning variation is sufficiently small within the allowable range for achieving the object of the present invention.

Whereas modifications of the present invention will be apparent to a person having ordinary skill in the art, to which the invention pertains, it is to be understood that embodiments as shown and described by way of illustrations are by no means intended to be considered in a limiting sense. Accordingly, it is to be intended to cover by claims all modifications which fall within the spirit and scope of the present invention.

What is claimed is:

1. A method of controlling a wavelength-selective light emitting device comprising: an array of plural semiconductor laser diodes differing in diffraction grating pitch; at least a multiplexer; and at least a modulator,
wherein an absorption edge wavelength of said modulator is controlled following to an oscillation wavelength of selected one of said plural laser diodes.

2. The method as claimed in claim 1, wherein said absorption edge wavelength is controlled by controlling said device in temperature.

3. The method as claimed in claim 2, wherein said temperature control is made so as to reduce a difference between variation of said oscillation wavelength of selected one of said plural laser diodes and variation of said absorption edge wavelength of said modulator.

4. The method as claimed in claim 3, wherein said plural semiconductor laser diodes and said modulator are controlled at different temperatures.

5. The method as claimed in claim 4, wherein said plural semiconductor laser diodes and said modulator are controlled by an external temperature controller which controls an entire region of said device uniformly in combination with applying a current to a resistive line which extends over both a laser diode region having said plural semiconductor laser diodes and a modulator region having said modulator, provided said resistive line is different in resistivity between said laser diode region and said modulator region.

6. The method as claimed in claim 4, wherein said plural semiconductor laser diodes and said modulator are controlled by an external temperature controller which controls an entire region of said device uniformly in combination with applying a current to a resistive line which extends over a laser diode region having said plural semiconductor laser diodes.

7. The method as claimed in claim 4, wherein said plural semiconductor laser diodes and said modulator are controlled by an external temperature controller which controls an entire region of said device uniformly in combination with applying a current to a resistive line which extends over a modulator region having said modulator.

8. The method as claimed in claim 4, wherein said plural semiconductor laser diodes and said modulator are controlled by an external temperature controller which controls an entire region of said device uniformly in combination with applying a current to a resistive line which extends over both a laser diode region having said plural semiconductor laser diodes and a multiplexer region having said multiplexer, so that a variation rate of said laser diode region is equal to a variation rate of said multiplexer region.

9. The method as claimed in claim 4, wherein said plural semiconductor laser diodes and said modulator are controlled by an external temperature controller which controls an entire region of said device uniformly in combination with applying a current to a resistive line which extends over both a semiconductor optical amplifier region having a semiconductor optical amplifier and a modulator region having said modulator, so that a variation rate of said semiconductor optical amplifier region is equal to a variation rate of said modulator region.

10. The method as claimed in claim 2, wherein said plural laser diodes are controlled in temperature in a temperature range having a center value which accords to a center value of said oscillation wavelength range, and a difference between a center value of said oscillation wavelength of selected one of said plural laser diodes and a center value of said absorption edge wavelength of said modulator is uniform for all of said plural laser diodes, and said diffraction grating pitch of each of said plural laser diodes is decided based on said controlled temperature of each of said plural laser diodes.

11. The method as claimed in claim 10, wherein said plural semiconductor laser diodes and said modulator are controlled at different temperatures.

12. The method as claimed in claim 11, wherein said plural semiconductor laser diodes and said modulator are controlled by an external temperature controller which controls an entire region of said device uniformly in combination with applying a current to a resistive line which extends over both a laser diode region having said plural semiconductor laser diodes and a modulator region having said modulator, provided said resistive line is different in resistivity between said laser diode region and said modulator region.

13. The method as claimed in claim 11, wherein said plural semiconductor laser diodes and said modulator are controlled by an external temperature controller which controls an entire region of said device uniformly in combination with applying a current to a resistive line which extends over a laser diode region having said plural semiconductor laser diodes.

14. The method as claimed in claim 11, wherein said plural semiconductor laser diodes and said modulator are controlled by an external temperature controller which controls an entire region of said device uniformly in combination with applying a current to a resistive line which extends over a modulator region having said modulator.

15. The method as claimed in claim 11, wherein said plural semiconductor laser diodes and said modulator are controlled by an external temperature controller which controls an entire region of said device uniformly in combination with applying a current to a resistive line which extends over both a laser diode region having said plural semiconductor laser diodes and a multiplexer region having said multiplexer, so that a variation rate of said laser diode region is equal to a variation rate of said multiplexer region.

16. The method as claimed in claim 11, wherein said plural semiconductor laser diodes and said modulator are controlled by an external temperature controller which controls an entire region of said device uniformly in combination with applying a current to a resistive line which extends over both a semiconductor optical amplifier region having a semiconductor optical amplifier and a modulator region having said modulator, so that a variation rate of said semiconductor optical amplifier region is equal to a variation rate of said modulator region.

17. The method as claimed in claim 2, wherein an entire region of said device is controlled at a uniform temperature which corresponds to selected one of said plural laser diodes, so that said absorption edge wavelength of said modulator follows to said oscillation wavelength of selected one of said plural laser diodes.

18. A method of controlling a wavelength-selective light emitting device comprising: a single semiconductor laser diode; a semiconductor optical amplifier; and a modulator,
wherein an absorption edge wavelength of said modulator is controlled following to an oscillation wavelength of selected one of said plural laser diodes.

19. The method as claimed in claim 18, wherein said absorption edge wavelength is controlled by controlling said device in temperature.

20. The method as claimed in claim 19, wherein said temperature control is made so as to reduce a difference between variation of said oscillation wavelength of selected one of said plural laser diodes and variation of said absorption edge wavelength of said modulator.

21. The method as claimed in claim 20, wherein said plural semiconductor laser diodes and said modulator are controlled at different temperatures.

22. The method as claimed in claim 21, wherein said plural semiconductor laser diodes and said modulator are controlled by an external temperature controller which controls an entire region of said device uniformly in combination with applying a current to a resistive line which extends over a laser diode region having said plural semiconductor laser diodes.

23. The method as claimed in claim 19, wherein said plural laser diodes are controlled in temperature in a temperature range having a center value which accords to a center value of said oscillation wavelength range, and a difference between a center value of said oscillation wavelength of selected one of said plural laser diodes and a center value of said absorption edge wavelength of said modulator is uniform for all of said plural laser diodes, and said diffraction grating pitch of each of said plural laser diodes is decided based on said controlled temperature of each of said plural laser diodes.

24. The method as claimed in claim 23, wherein said plural semiconductor laser diodes and said modulator are controlled at different temperatures.

25. The method as claimed in claim 24, wherein said plural semiconductor laser diodes and said modulator are controlled by an external temperature controller which controls an entire region of said device uniformly in combination with applying a current to a resistive line which extends over a laser diode region having said plural semiconductor laser diodes.

26. A wavelength-selective light emitting device comprising:
an array of plural semiconductor laser diodes differing in diffraction grating pitch;
at least a multiplexer;
at least a modulator;
a temperature controller for controlling said device in temperature, so that an absorption edge wavelength of said modulator is controlled following to an oscillation wavelength of selected one of said plural laser diodes.

27. The device as claimed in claim 26, wherein said temperature controller controls said device in temperature so as to reduce a difference between variation of said oscillation wavelength of selected one of said plural laser diodes and variation of said absorption edge wavelength of said modulator.

28. The device as claimed in claim 27, wherein said plural semiconductor laser diodes and said modulator are controlled at different temperatures.

29. The device as claimed in claim 28, wherein said temperature controller comprises:
an external temperature controller which controls an entire region of said device uniformly; and
a resistive line which extends over both a laser diode region having said plural semiconductor laser diodes and a modulator region having said modulator, provided said resistive line is different in resistivity between said laser diode region and said modulator region.

30. The device as claimed in claim 28, wherein said temperature controller comprises;
an external temperature controller which controls an entire region of said device uniformly; and
a resistive line which extends over a laser diode region having said plural semiconductor laser diodes.

31. The device as claimed in claim 28, wherein said temperature controller comprises:
an external temperature controller which controls an entire region of said device uniformly; and
a resistive line which extends over a modulator region having said modulator.

32. The device as claimed in claim 28, wherein said temperature controller comprises:
an external temperature controller which controls an entire region of said device uniformly; and
a resistive line which extends over both a laser diode region having said plural semiconductor laser diodes and a multiplexer region having said multiplexer, so that a variation rate of said laser diode region is equal to a variation rate of said multiplexer region.

33. The device as claimed in claim 28, wherein said temperature controller comprises:
an external temperature controller which controls an entire region of said device uniformly; and
a resistive line which extends over both a semiconductor optical amplifier region having a semiconductor optical amplifier and a modulator region having said modulator, so that a variation rate of said semiconductor optical amplifier region is equal to a variation rate of said modulator region.

34. The device as claimed in claim 19, wherein said temperature controller controls said plural laser diodes in temperature in a temperature range having a center value which accords to a center value of said oscillation wavelength range, and said temperature controller controls said device in temperature so that a difference between a center value of said oscillation wavelength of selected one of said plural laser diodes and a center value of said absorption edge wavelength of said modulator is uniform for all of said plural laser diodes, and said diffraction grating pitch of each of said plural laser diodes is decided based on said controlled temperature of each of said plural laser diodes.

35. The device as claimed in claim 34, wherein said temperature controller controls said plural semiconductor laser diodes and said modulator at different temperatures.

36. The device as claimed in claim 35, wherein said temperature controller comprises:
an external temperature controller which controls an entire region of said device uniformly; and
a resistive line which extends over both a laser diode region having said plural semiconductor laser diodes and a modulator region having said modulator, provided said resistive line is different in resistivity between said laser diode region and said modulator region.

37. The device as claimed in claim 35, wherein said temperature controller comprises:
an external temperature controller which controls an entire region of said device uniformly; and
a resistive line which extends over a laser diode region having said plural semiconductor laser diodes.

38. The device as claimed in claim 35, wherein said temperature controller comprises:
an external temperature controller which controls an entire region of said device uniformly; and
a resistive line which extends over a modulator region having said modulator.

39. The device as claimed in claim 35, wherein said temperature controller comprises:
an external temperature controller which controls an entire region of said device uniformly; and
a resistive line which extends over both a laser diode region having said plural semiconductor laser diodes and a multiplexer region having said multiplexer, so that a variation rate of said laser diode region is equal to a variation rate of said multiplexer region.

40. The device as claimed in claim 35, wherein said temperature controller comprises:
an external temperature controller which controls an entire region of said device uniformly; and
a resistive line which extends over both a semiconductor optical amplifier region having a semiconductor optical amplifier and a modulator region having said modulator, so that a variation rate of said semiconductor optical amplifier region is equal to a variation rate of said modulator region.
